(19) United States
(12) Patent Application Publication
(10) Pub. No.: US 2010/0157644 A1
(43) Pub. Date: Jun. 24, 2010

(54) Configurable memory interface to provide serial and parallel access to memories

(75) Inventor: Robert Norman, Pendleton, OR (US)

Correspondence Address: UNITY SEMICONDUCTOR CORPORATION, 255 SANTA ANA COURT, SUNNYVALE, CA, 94085-4511, US

(73) Assignee: UNITY SEMICONDUCTOR CORPORATION, Sunnyvale, CA (US)

(21) Appl. No.: 12/587,841

(22) Filed: Oct. 13, 2009

Related U.S. Application Data
(60) Provisional application No. 61/203,203, filed on Dec. 19, 2008.

(51) Int. Cl. G11C 5/02; G11C 7/00; G11C 5/06

(52) U.S. Cl. 365/51; 365/191; 365/63; 365/219

(57) ABSTRACT

The invention relates to an interface for providing multiple modes of accessing data, including serial and parallel modes. Controllable non-volatile memory interfaces are described, including a serial module configured to provide a serial connection between a non-volatile memory array and another non-volatile memory array. The serial module can provide access to the non-volatile memory array. A mode module can be configured to determine which type of interface operation (i.e., serial mode or parallel mode) will be used for the non-volatile memory array and the another non-volatile memory array. In some cases, a controller can be configured to select the serial module independent of the mode module. Circuitry for performing data operations on the non-volatile memories can be fabricated FEOL on a substrate and the non-volatile memories can be fabricated BEOL directly on top of the substrate in one or more layers of memory.

### FIELD OF THE INVENTION

The present invention relates generally to data storage technology. More specifically, the present invention relates to an interface for providing multiple modes of accessing data, including serial and parallel modes.

### BACKGROUND

Non-volatile memory has been used for mass storage applications. In particular, Flash memories have been adapted for use with NAND architectures to support mass storage applications. In typical Flash-based configurations, a controller manages file systems for storing data, and provides memory access in blocks. A block is a superset of a number of pages, and each page can be 512 or more bytes in size. While writing and reading is performed typically on a page-by-page basis, erasing the memory in a Flash NAND memory usually is done on a block-by-block basis. Thus, Flash memories generally require computational overhead to maintain file systems. In some implementations, each discrete array of Flash memory can require a dedicated chip selection pin to activate the array. Thus, multiple arrays may require a relatively large number of dedicated lines that can increase a number of pins or lines from a host. Furthermore, NOR structured memories are generally parallel in nature (e.g., with parallels sets of address and data pins). Such memories typically are not well suited to be compatible with interfaces for NAND structured memories that are generally designed to support very large capacities of Memory. A serial interface approach is a better solution for reducing pins. An interface is serial in nature (e.g., address bits and data bits may be shifted to the memories in series).

There are continuing efforts to improve data storage interface technologies.

### BRIEF DESCRIPTION OF THE DRAWINGS

Various embodiments of the invention are disclosed in the following detailed description and the accompanying drawings:

FIG. 1A depicts an example of an interface configured to provide parallel modes and/or serial modes of memory access, in accordance with at least some embodiments of the invention;

FIG. 1B depicts another example of an interface configured to provide parallel modes and/or serial modes of memory access, in accordance with at least some embodiments of the invention;

FIG. 2 depicts an example of a serial module in accordance with at least some embodiments of the invention;

FIGS. 3A and 3B depict flows as examples of methods to perform various operations in accordance with various embodiments of the invention;

FIG. 4A depicts an implementation of serial modules in accordance with at least some embodiments of the invention;

FIGS. 4B and 4C depict an interface implemented in multiple layers of memory in accordance with various embodiments of the invention;

FIGS. 5A and 5B depict examples of logic for implementing assignment modes in accordance with various embodiments of the invention;

FIGS. 6A and 6B depict examples of logic for implementing selection of serial modules in accordance with various embodiments of the invention;

FIG. 7A depicts an example of memory cells positioned in a two-terminal cross-point array;

FIG. 7B depicts a single layer or multiple vertically stacked layers of memory arrays formed BEOL on top of a base layer die including circuitry formed FEOL;

FIG. 7C depicts one example of a vertically stacked memory including multiple array layers that share conductive array lines and formed BEOL directly on top of a previously formed FEOL base layer;

FIG. 8A depicts a cross-sectional view of an integrated circuit die including a single layer of memory fabricated over a substrate including active circuitry fabricated on the substrate in a logic layer;

FIG. 8B depicts a cross-sectional view of an integrated circuit die including vertically stacked layers of memory fabricated over a substrate including active circuitry fabricated on the substrate in a logic layer;

FIG. 8C depicts an integrated circuit die including vertically stacked layers of memory with shared conductive array lines fabricated over a substrate including active circuitry fabricated on the substrate in a logic layer;

FIG. 9 depicts a memory system including a non-volatile two-terminal cross-point array;

FIG. 10 depicts an exemplary electrical system that includes at least one non-volatile two-terminal cross-point array; and

FIG. 11 depicts top plan views of a wafer processed FEOL to form a plurality of base layer die including active circuitry and the same wafer subsequently processed BEOL to form one or more layers of memory directly on top of the base layer die where the finished die can subsequently be singulated, tested, and packaged into integrated circuits.

Although the previous drawings depict various examples of the invention, the invention is not limited by the depicted examples. It is to be understood that, in the drawings, like reference numerals designate like structural elements. Also, it is understood that the depictions in the FIGS. are not necessarily to scale.

### DETAILED DESCRIPTION

Various embodiments or examples of the invention may be implemented in numerous ways, including as a system, a process, an apparatus, or a series of program instructions on a computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims, and numerous alternatives, modifications, and equivalents are encompassed. Numerous specific details are set forth in the following description in order to provide a thorough understanding. These details are provided as examples and the described techniques may be practiced according to the claims without some or all of the accompanying details. For clarity, technical material that is known in the technical fields related to the examples has not been described in detail to avoid unnecessarily obscuring the description.

U.S. patent application Ser. No. 11/095,026, filed Mar. 30, 2005 and entitled “Memory Using Mixed Valence Conductive Oxides,” now U.S. Published Application No. 2006/0171200, is hereby incorporated by reference in its entirety for all purposes and describes non-volatile third dimensional memory elements that may be arranged in a two-terminal, cross-point memory array. New memory structures are possible with the capability of this third dimensional memory array. In at least some embodiments, a two-terminal memory element or memory cell can be configured to change conductivity when exposed to an appropriate voltage drop across the two-terminals. The memory element can include an electrolytic tunnel barrier and a mixed valence conductive oxide. A voltage drop across the electrolytic tunnel barrier can cause an electrical field within the mixed valence conductive oxide that is strong enough to move oxygen ions out of the mixed valence conductive oxide and into the electrolytic tunnel barrier. When certain mixed valence conductive oxides (e.g., praseodymium-calcium-manganese-oxygen perovskites and lanthanum-nickel-oxygen perovskites) change valence, their conductivity changes. Additionally, oxygen accumulation in certain electrolytic tunnel barriers (e.g., yttrium stabilized zirconia) can also change conductivity. If a portion of the mixed valence conductive oxide near the electrolytic tunnel barrier becomes less conductive, the tunnel barrier width effectively increases. If the electrolytic tunnel barrier becomes less conductive, the tunnel barrier height effectively increases. Both mechanisms can be reversible if the excess oxygen from the electrolytic tunnel barrier flows back into the mixed valence conductive oxide. A memory can be designed to exploit tunnel barrier height modification, tunnel barrier width modification, or both.

In some embodiments, an electrolytic tunnel barrier and one or more mixed valence conductive oxide structures do not need to operate in a silicon substrate, and, therefore, can be fabricated (e.g., BEOL) above circuitry being used for other purposes (e.g., fabricated FEOL). Further, a two-terminal memory cell can be arranged as a cross point such that one terminal is electrically coupled with an X-direction line (or an “X-line”) and the other terminal is electrically coupled with a Y-direction line (or a “Y-line”). A third dimensional memory can include multiple memory cells vertically stacked upon one another, sometimes sharing X-direction and Y-direction lines in a layer of memory, and sometimes having isolated lines. When a first write voltage, VW1, is applied across the memory cell (e.g., by applying ½ VW1 to the X-direction line and ½-VW1 to the Y-direction line), the memory cell can switch to a low resistive state. When a second write voltage, VW2, is applied across the memory cell (e.g., by applying ½ VW2 to the X-direction line and ½-VW2 to the Y-direction line), the memory cell can switch to a high resistive state. Memory cells using electrolytic tunnel barriers and mixed valence conductive oxides can have VW1 opposite in polarity from VW2.

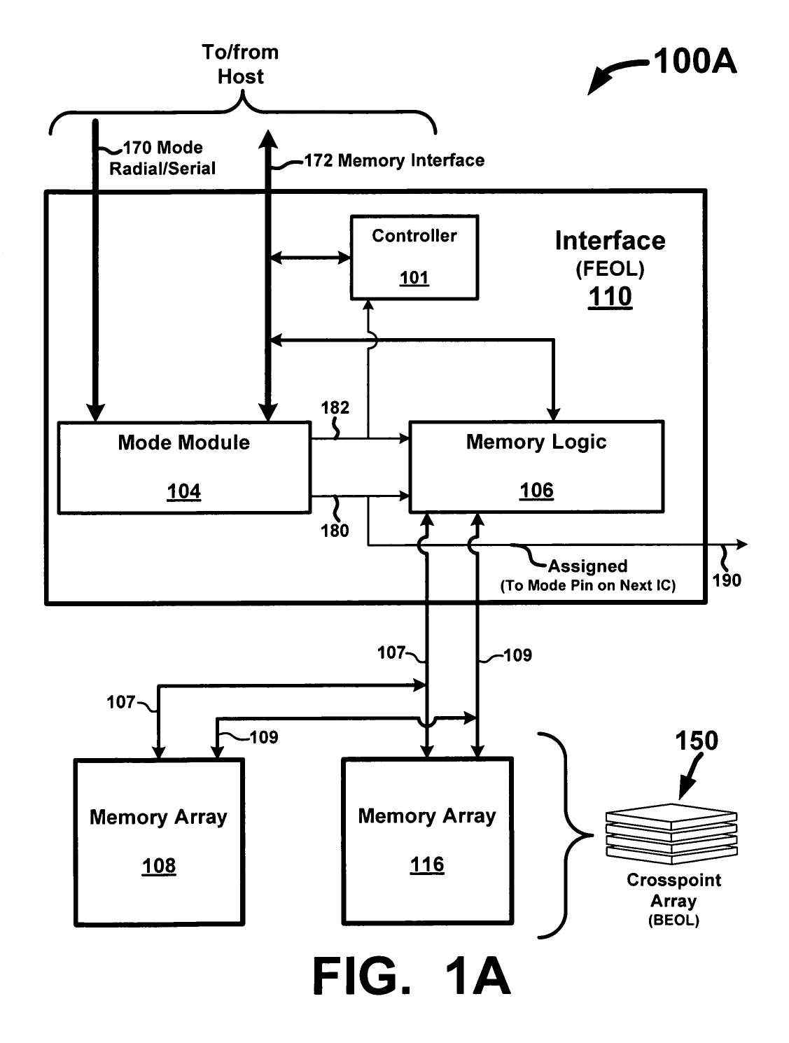

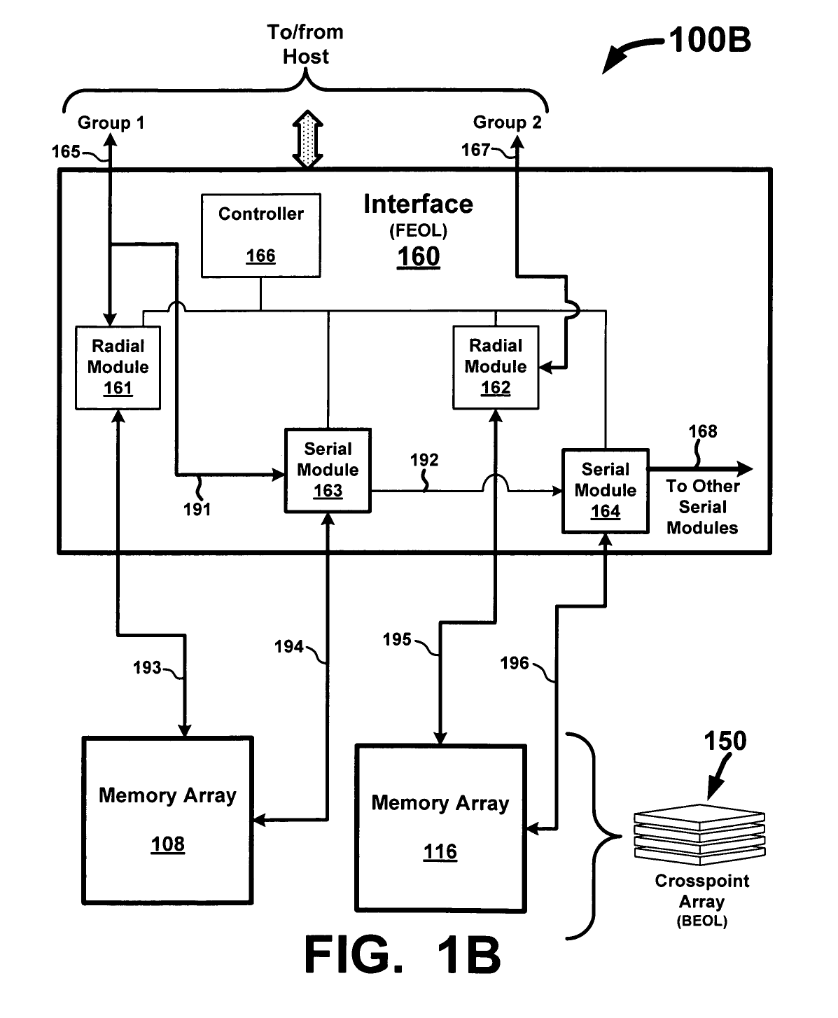

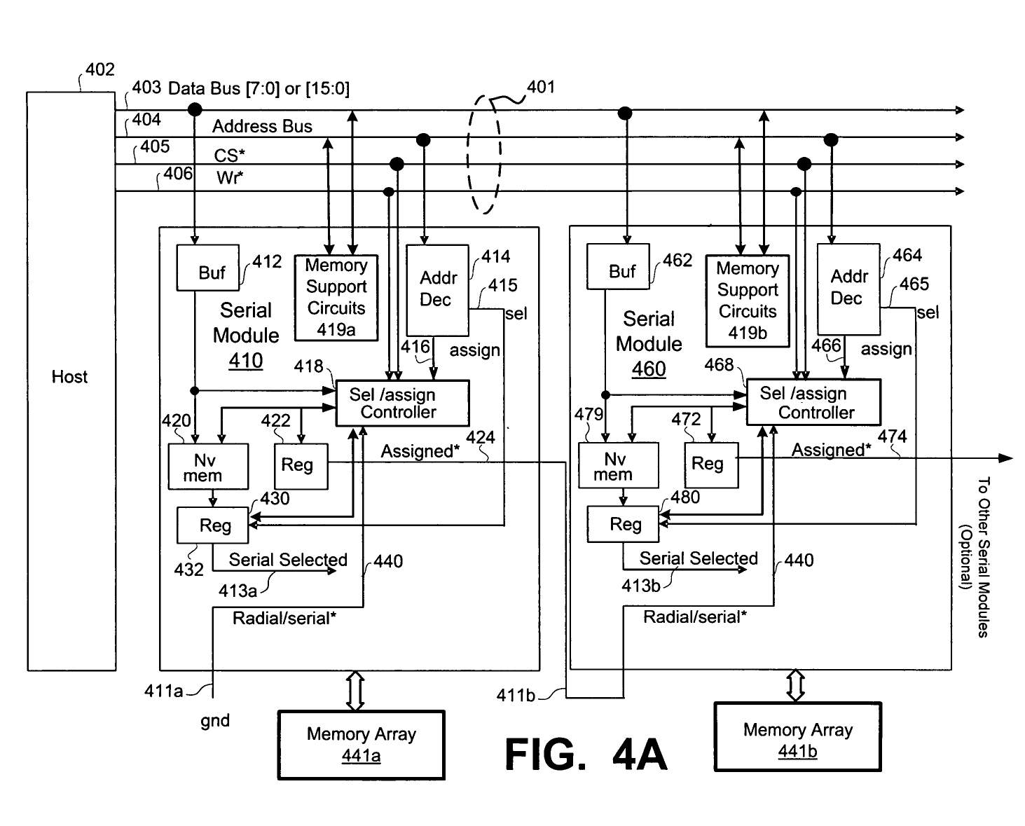

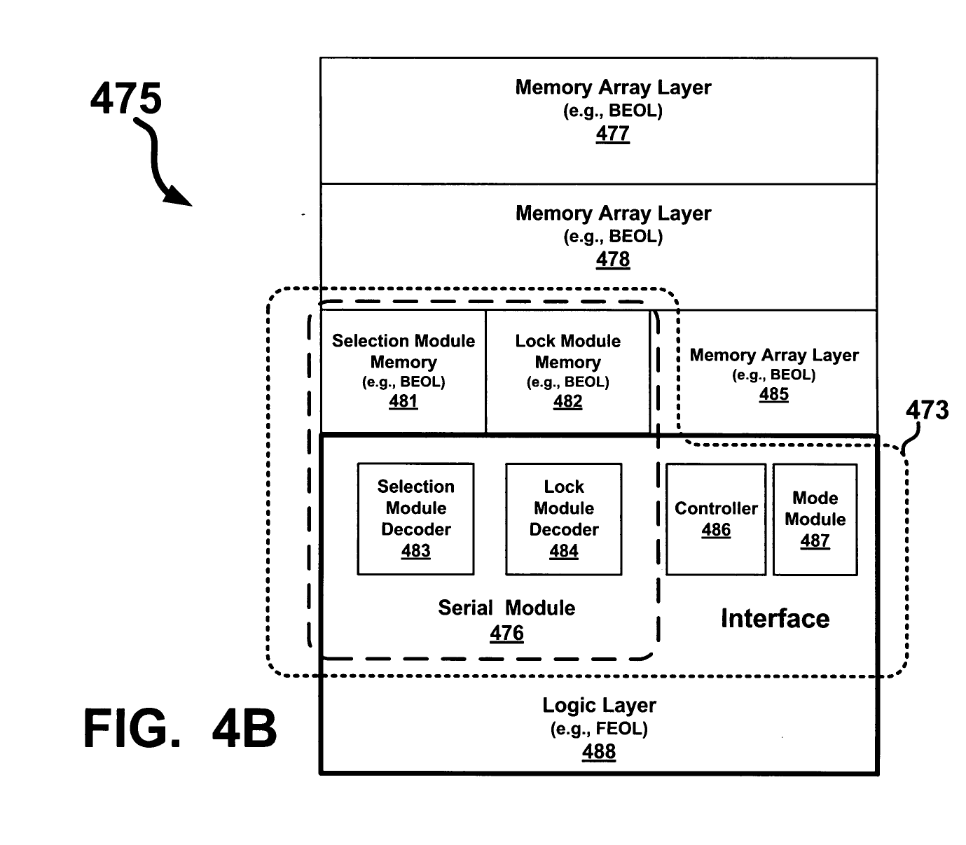

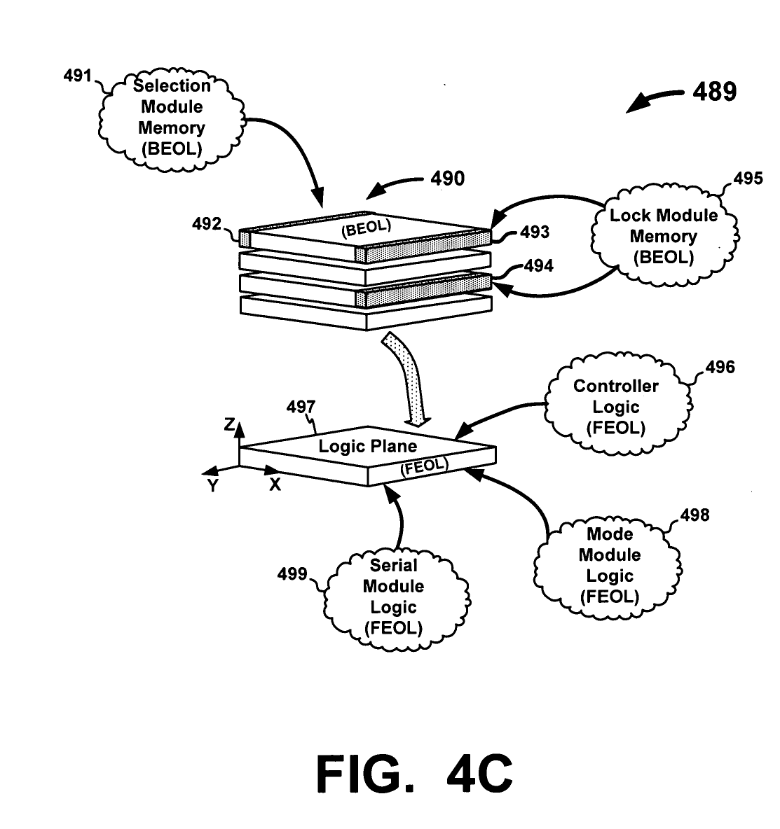

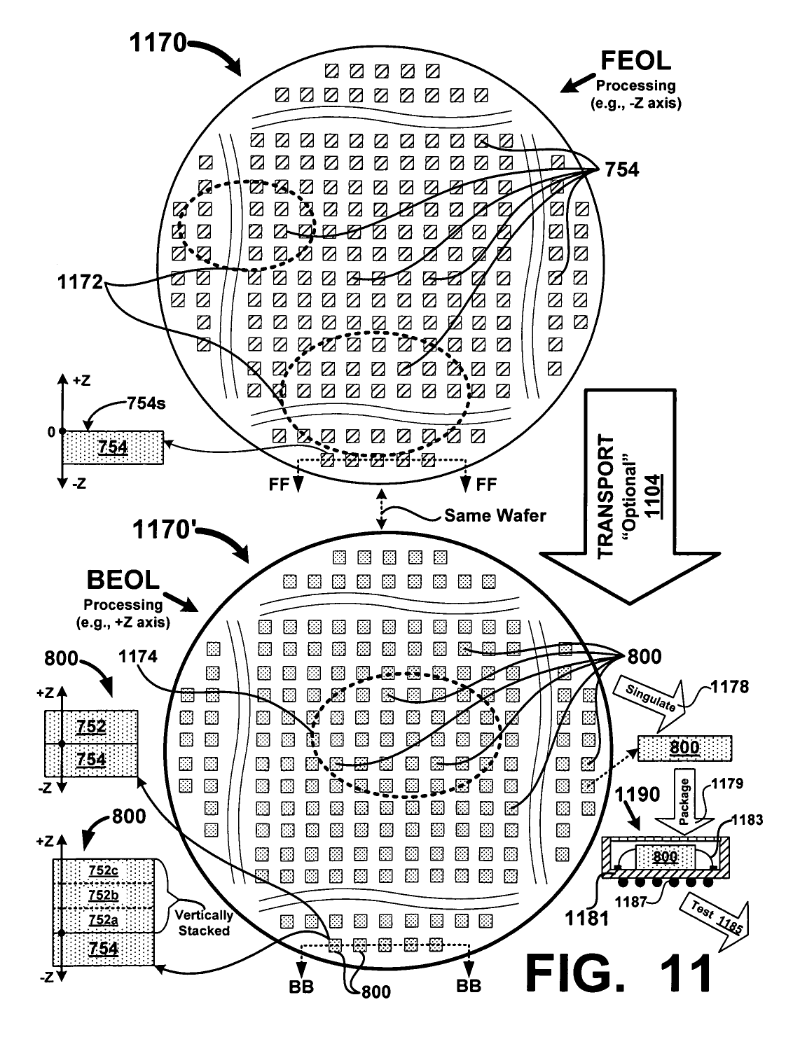

FIG. 1A depicts a memory system 100A configured for operating in either serial mode or parallel mode (e.g., a radial mode) with essentially any given type of memory interface. The memory can be made to operate in either the serial mode or the radial mode of operation via a logic value (e.g., a logic “0” or logic “1”) on a mode pin and operating sequences that will be described below. In a conventional radial mode, each chip gets an independent chip select and responds directly to a signal on its respective chip select. This is the mode by which conventional memory chips are used in most systems. To eliminate the routing of separate chip selects to each memory chip, the serial mode was developed. In order for a plurality of memory chips to share a common chip select, a differentiation scheme between the plurality of chips is required so that each chip only responds to signal(s) intended for that chip. A method of assigning a unique address for each chip was developed. To make the system work an assign sequence is implemented so that only chips that are assigned respond to data operations. This sequence is accomplished by the use of a mode pin and an assigned output pin (assigned pin). Buy connecting the assigned pin of one chip to the mode pin of another chip in a sequence of chips, a unique assign method is enabled. Initially, all chips are placed in a default radial mode with the assigned pins of all chips set to an inactive state. The first chip in the sequence is either tied to a serial mode logic level or is activated by a signal from a controller which drives the serial mode logic level on the mode pin of the first chip in the sequence. In FIG. 1A, upon activation of a mode radial/serial pin 170 (mode pin 170) to a logic level for the serial mode, the first chip in the sequence becomes active and responds to signals from memory interface 172. Signals on memory interface 172 can be generated by a host (e.g., a computer) or some other system (not shown). The memory interface 172 (interface 172) can included address busses, data busses, and other signals including but not limited to signals for data operations on memory. The first chip with its mode pin 170 in serial mode will now partially respond to signals on interface 172. No memory activity will be allowed until the chip is actually selected for memory activity (e.g., data operations) and no chip can become selected until it is assigned. To assign a chip, interface 172 puts a value to be assigned to the chip on a data bus (not shown) and performs a write sequence with the interface 172 signals to a unique assign address. When a controller 101 performs a bus write cycle, the memory in serial mode will activate its mode module 104 and associated logic circuits and store data on interface 172 in a non-volatile memory (e.g., memory array 108 and/or memory array 116) or in a non-volatile register. Upon completion of the bus write, the assign value will have been stored in the non-volatile memory or the non-volatile register and a non-volatile bit will be set. Setting of the non-volatile bit indicates the chip has been assigned an address that is stored in its non-volatile assign location. Signal 180 represents this special non-volatile control bit. Placing the chip in the assigned state enables controller 101 and memory logic 106 to proceed with normal operation. Normal operation is defined as a selection of a chip followed by normal read and write operations. Memory logic 106 includes logic and/or circuitry including but not limited to address decoders, multiplexers, data buffers, data and address steering circuits, and other circuitry necessary to interface with the non-volatile memories (108, 116) and/or non-volatile registers. The initiation of a selection of a specific chip can be performed by a host or some other system in signal communication with interface 172. The selection process can include performing a write cycle to a unique address that is assigned for the select function. When this type of write operation occurs, all chips that are connected with interface 172 will evaluate this cycle if those chips have been assigned a serial address. When this special select write occurs, the host places the address of a memory device it wishes to talk to on a data bus (not shown) of interface 172. All assigned chips look at this value and compare it to the value stored in its non-volatile assign location. If the two values match, then the chip becomes selected and logic signal 182 is set. The setting of logic signal 182 is operative to activate the controller 101 and memory logic 106. The chip now responds to all read and write operations over interface 172 and will allow access for data operations to memory devices controlled by that chip (e.g., memory arrays 108 through 116). Any bus operation during the select sequence will be evaluated by the selected chip. If the select address is changed the chip becomes deselected and will stop responding to any further operations on interface 172 until another select cycle is successfully completed. Data operations memory devices in deselected chips are disabled until those chips become selected again. The next chip in the system to be assigned will be the one connected to the output of the assigned pin 190 of the chip just described. The next chip requires the above mentioned assign sequence and select sequence be performed before that chips memory devices can be enabled for data operations. After successful assign and select sequences on the next chip, there are two chips that can be uniquely selected and be operated on. The same sequence of assignments can be made for however many chips are connected as described above (e.g., assigned pin 190 to mode pin 170). It can be seen that by going through this sequence one time at beginning at first system initialization, the chips will all operate in serial mode at power on and will not require any further initialization sequences. This is possible because of the non-volatile resistive memory used as the storage media of the assign value. The non-volatile memory layers in stack 150 can be fabricated BEOL directly on top of a substrate (e.g., a silicon wafer) that includes active circuitry (e.g., CMOS circuitry) fabricated FEOL on the substrate and configured for performing data operations on the memory array(s) in the memory layers (see FIGS. 4B and 4C). The active circuitry can include the circuitry in the interface 110. A die (e.g., a die from a silicon wafer) including the FEOL active circuitry and the BEOL memory layers 150 can be packaged in an appropriate package to form an integrated circuit (IC) as described below in regards to FIG. 11.

In view of the foregoing, interface 110 can decrease the number of terminals to which chip select signals (or other signals) are to be applied, thereby decreasing the number of leads or pins for a semiconductor package or system that uses multiple memory arrays. Further, interface 110 can be adapted to interface memory arrays of non-volatile third dimensional memory elements that can be arranged in a two-terminal, cross-point memory array, such as stack 150. As the non-volatile third dimensional memory elements can be configured to emulate memory types including but not limited to FLASH, SRAM, DRAM or a combination of those memory types, for example, interface 110 can be configured to provide different configurations of control, address and data signals in radial mode or serial mode. Thus, interface 110 can be adapted to facilitate functionalities found in NOR FLASH structured memories and/or NAND FLASH structured memories. Unlike DRAM or SRAM, the non-volatile third dimensional memory elements retain stored data in the absence of power and do not require an external power source (e.g., a back-up battery or a capacitor) to retain stored data when main power is turned off.

As used herein, the term “parallel” can be used interchangeably with “radial,” according to some embodiments. As used herein, the term “chip selection” can be used interchangeably with “array selection,” according to some embodiments. As used herein, the term “chip” can be used interchangeably with the term integrated circuit “IC,” according to some embodiments. In some embodiments, controller 101 is optional and functionality can be provided by a host, which is not shown.

FIG. 1B depicts another example of an interface configured to provide parallel modes and/or serial modes of memory access, in accordance with at least some embodiments of the invention. Diagram 1008 depicts an interface 160 including a controller 166, a radial module 161, a radial module 162, a serial module 163, and a serial module 164. Interface 160 can be configured to provide either serial access or parallel access between a host (not shown) and memory arrays 108 and 116. In parallel mode, the host can be coupled via separate control lines (and optionally via separate address and data lines) to memory arrays 108 and 116. For example, the host can be coupled at terminal 165 to provide a group of signals group 1 (e.g., control, address, and/or data signals), including a chip select signal to memory array 108, and can be coupled at terminal 167 to provide another group of signals group 2 (e.g., control, address, and/or data signals), including another chip select signal, to memory array 116. In serial mode, the host can be coupled via shared lines that can share groups of signals (e.g., groups of control, address, and/or data signals) to memory arrays 108 and 116. For example, the host can be coupled at terminal 165 to transmit multiple chip select signals (or equivalents thereof), such as one group of signals via path 191 to memory array 108 or another group of signals via paths 191 and 192 to memory array 116, thereby obviating the need for using terminal 167 to provide other chip select groups of signals, which can include chip select signals. Memory arrays 108 and 116 are electrically coupled with their respective radial and serial modules in interface 160 using paths 193, 194, 195, and 196. Output 168 from serial module 164 can be electrically coupled with the inputs of other serial modules (not shown). In at least some embodiments, array selection can be provided by transmitting commands serially via serial paths (e.g., shared control, address, and/or data lines). In at least some embodiments, memory arrays 108 and 116 can be disposed in the stack 150 in memory layers. As described above in reference to FIG. 1A, circuitry for interface 160 can be fabricated FEOL and the memory layers in stack 150 can be fabricated BEOL.

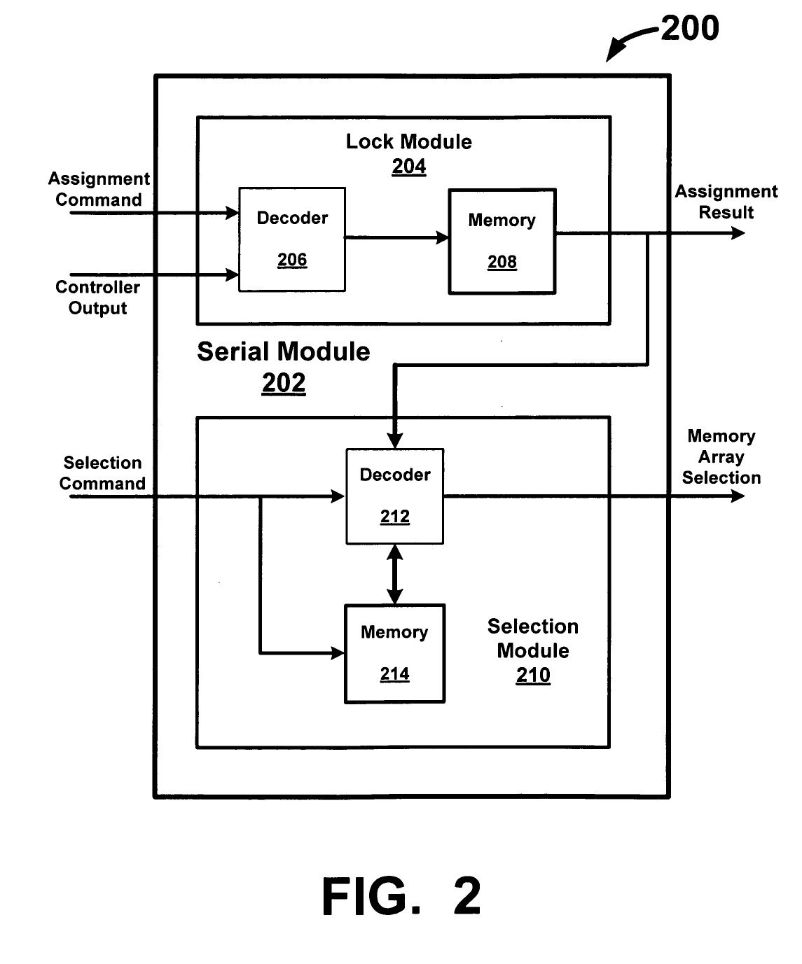

FIG. 2 depicts an example of a serial module in accordance with at least some embodiments of the invention. Diagram 200 shows that serial module 202 can include a lock module 204 and a selection module 210. Lock module 204 can be configured to adapt a memory array to operate in serial mode. In some embodiments, lock module 204 can be configured to assign an associated memory array with an identifier that distinguishes the memory array from other memory arrays (not shown) that can share a group of one or more buses. Further, lock module 204 can be configured to lock the memory array from being assigned a different identifier. In at least some embodiments, lock module 204 can include a decoder 206 and a memory 208. In operation, decoder 206 can receive an assignment command via the group of one or more buses to initiate an assignment operation, and can receive an output via the group of one or more buses from a controller or host (e.g., “controller output”), which can include the value of the identifier. In operation, decoder 206 can program the identifier into memory 208. Lock module 204 can generate an assignment result specifying either the value of the identifier or that the memory array has been assigned, or both. In at least some embodiments, selection module 210 can include a decoder 212 and a memory 214, and can be configured to receive a selection command that initiates selection of a memory array via the group of one or more buses and the assignment result. Decoder 212 can be configured to determine whether an identifier associated with the selection command matches the assignment result. If so, the associated memory has been selected for access. Once selected, decoder 212 can be configured to store a state in memory 214 that specifies that the associated memory is selected. Therefore, serial module 202 enables access to the memory array, whereas other serial modules (not shown) that are not selected will have unselected states stored in their respective memories, which can function similar to memory 214. As described above, memory 208 and/or 214 can be non-volatile BEOL memory fabricated directly on top of a substrate including FEOL active circuitry and the FEOL active circuitry can implement some or all of the circuitry portions of the serial module 202. In other embodiments, memory 208 and/or 214 can be non-volatile registers can be BEOL registers.

It should be noted that partitioning the memory array into selectable boundaries can be done by duplication of the just described serial module 202 for each partition. In addition the different select bits in a device would be applied to memory logic 106. These select bits would act as enablers for the partitioned memory such as the planes. For example, select address “01” can enable memory plane 1 and only memory plane 1 for access. FIG. 4A will depict this in greater detail. This feature will allow for a host system to control access to memory in a more controlled manner and offers an additional degree of protection from file over writes. It should also be noted that memory 214 and/or 208 can a non-volatile memory or non-volatile register as described herein. When this feature is added, the memory that was last selected will be the memory that will be selected at power up, allowing the host to fetch data (e.g., perform a data read) immediately from the memory selected at power up without requiring a select sequence first. The power up feature can be used to enable the host to fetch code (e.g., computer readable instructions or the like) on power up, allowing the memory to be the boot memory of the system. Here, the code can be programming instructions for a DSP, a CPU, a FPGA, a programmable logic device (PLD), a microprocessor (μP), a microcontroller (μC) or an embedded controller, for example. In some applications, the data fetched from the non-volatile memory can include both code and data to be used by the host system. Alternatively, the power up feature can be used to allow the host to fetch other types of data (e.g., non-code data) at power up. Here, the host or other system can be in signal communication (e.g., wired or wireless communication) with the memory interface and read the code or data off of the memory interface.

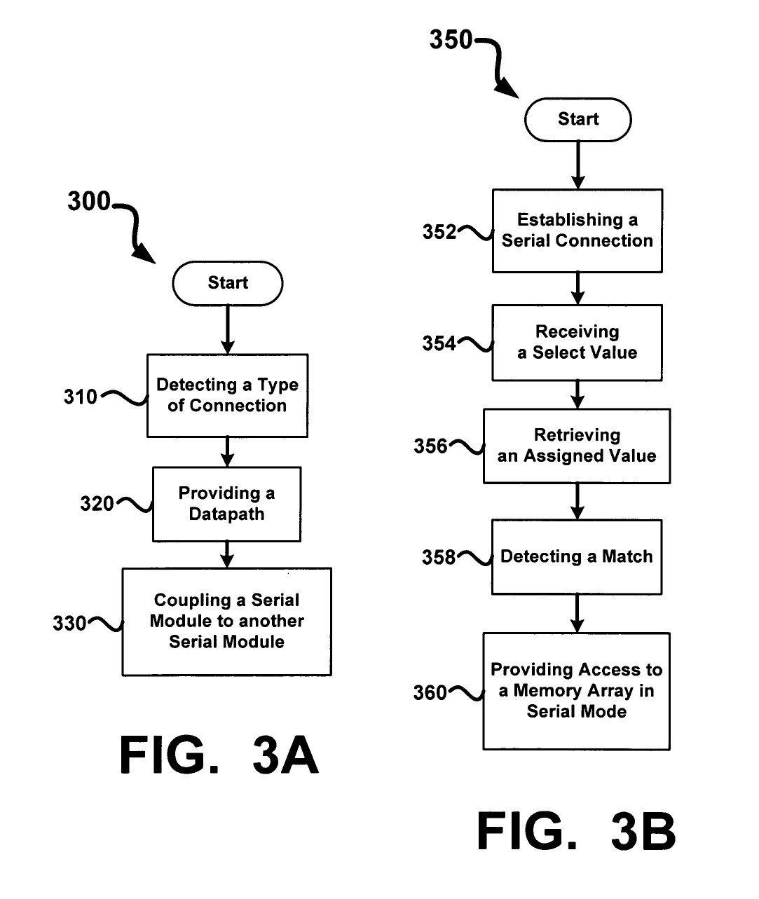

FIGS. 3A and 3B depict flow charts as examples of methods to perform various operations in accordance with various embodiments of the invention. FIG. 3A depicts a flow 300 to perform an assignment operation in serial mode, according to some embodiments. At a stage 310, flow 300 detects a type of connection to determine whether, for example, a serial module is in serial mode. For example, a serial module can monitor a radial/serial terminal (e.g., mode pin 170) to determine its state, whereby a high state can be indicative of a radial mode and a low state can be indicative of a serial mode. For example, if a logical zero (“0”) is applied to the radial/serial terminal, the serial module operates in serial mode, whereas if a logical one (“1”) is applied to the radial/serial terminal, the serial module operates in either in parallel mode (if configured in a parallel configuration with separate buses) or is otherwise disabled (if configured in a series configuration with shared buses). At a stage 320, a data path can be provided to transmit an identifier (or an assignment value) to the serial module. The identifier can be used to assign the serial module with a unique assignment value (e.g., a memory array number). At a stage 330, flow 300 couples the serial module to another serial module to transmit, for example, a state specifying that the serial module has been assigned, such that the state can configure the other serial module to operate in assignment mode. Once a device has its ID address written to the special ID memory or non-volatile register it completes the serial assignment and passes that state to its output for use by the attached device to complete an identical sequence just performed on the above described chip.

FIG. 3B depicts a flow 350 to perform a selection operation in serial mode, according to some embodiments. At a stage 352, a host attempts a serial connection by placing the desired select ID on the host interface bus. At a stage 354, a select value can be received. In some embodiments, the select value can accompany a command to select a memory array, the select value specifying a memory array that is to be selected from a pool of different select values. At a stage 356, an assigned value stored in association with the serial module can be retrieved, the assigned value being generally stored in a memory associated with a lock module or equivalent structures. At a stage 358, a match between the assigned value and the select value can be determined, the match signifying that the associated serial module and memory array are being selected. At a stage 360, the serial module can indicate that it is selected to perform other memory-related operations, such as reading and writing. For example, the serial module can generate a serial selected signal that can indicate to elements within and without that the serial module has been selected.

FIG. 4A depicts an implementation of serial modules in accordance with at least some embodiments of the invention. In this example, serial modules 410 and 460 are configured to share a group 401 of one or more buses and control signals among multiple memory arrays (not shown). Group 401 can include a data bus 403, an address bus 404, a chip select (“CS”) signal line 405, and a write (“WR*”) signal line 406. As shown, group 401 can couple a host 402 to a memory array 441a and a memory array 441b via serial module 410 and serial module 460, respectively. Examples of host 402 include a processor, a computer, a DMA engine, and other memory-consuming devices. Serial module 410 can include a buffer (“buf”) 412, which can be optional, an address decoder (“addr dec”) 414, a select/assign controller (“sel/assign controller”) 418, a memory (“nv mem”) 420, a register (“reg”) 422, and a register (“reg”) 432. Serial module 410 also can include a radial/serial mode select terminal 411a configured to operate serial module 410 in either serial mode or parallel (e.g., radial) mode. Thus serial mode can use a terminal for a chip select (“CS”) signal line 405 and a radial/serial mode select terminal (411a, 411b) to access multiple memories, rather than separate terminals for each chip select signal for each memory in parallel mode (e.g., six chip select pins for six memories coupled to a host in parallel). The above-described elements in serial module 410 can be used to assign a unique assignment value to serial module 410, during an assignment mode of operation, and to distinguish serial module 410 from other serial modules, during a run mode of operation, to specifically access serial module 410 for writing and reading data, among other things. Serial module 460 can include a buffer (“buf”) 462, which can be optional, an address decoder (“addr dec”) 464, a select/assign controller (“sel/assign controller”) 468, a memory (“nv mem”) 479, a register (“reg”) 472, and a register (“reg”) 480, each of which can have equivalent structures and/or functionality as similarly-named elements described in connection with serial module 410.

Buffer 412 can be configured to store a value from data bus 403, such as a value that identifies a serial module, such as serial module 410, that is being accessed serially. The value can be an assignment value of “00” that can uniquely identify serial module 410 during an assignment mode, and, thus, can be used to identify serial module 410 as memory “00” to distinguish it from among other serial modules, such as serial module 460, during run mode for memory-select related commands. Further, buffer 412 can be used during run mode to transmit or receive data representing write data or read data, depending on a memory-access related command (e.g., a command that accesses a memory array to perform a memory operation, such as a write or a read operation). Memory 420 can be configured to store the assignment value for serial module 410 in a non-volatile manner to preserve its identity in serial mode after power is restored. Register 432 can be configured to generate a serial selected signal via path 413a that indicates to other elements (e.g., memory support circuits 419a) that serial module 410 is operating in serial mode. Register 422 can be configured to store a state that indicates whether serial module 410 has been assigned with an assignment value or is unassigned. As such, register 422 can be used to determine whether to respond to signals in group 401 based on a selected value that specifies serial module 410.

Address decoder 414 can be configured to decode data on address bus 404 to determine commands for performing an operation, such as an operation in either assignment mode or run mode. For example, address decoder 414 can decode a first set of data (e.g., 1010) that represents an assignment/selection command, and, in response to the command, address decoder 414 can generate a first set of control signals (e.g., associated with an assignment mode) to control operation of, for example, select/assign controller 418 and register 422. Address decoder 414 can decode a second set of data (e.g., 1011) that represents an assignment/selection command, and, in response to the command, address decoder 414 can generate a second set of control signals (e.g., associated with a run mode) to control operation of, for example, select/assign controller 418 and register 432. In some embodiments, a set of data (e.g., 1011) can represent an assignment/selection command that can be used in combination with the state of register 422. For example, if the state of register 422 indicates that serial module 410 is unassigned, then address decoder 414 can process the set of data on data bus 403 to cause serial module 410 to assign an assignment value to serial module 410, whereas if the state of register represents an assigned state, then address decoder 414 can process the set of data to perform run mode operations, including a select operation or a memory access operation.

Select/assign controller 418 can be configured to program memory 420 with an assignment value from buffer 412 responsive, for example, to an assign signal via path 416 from address decoder 414 in assignment mode. Select/assign controller 418 also can set the state of register 422 to indicate that serial module 410 has been assigned with an identifier. In serial mode, select/assign controller 418 can be configured to receive a select value from buffer 412 (i.e., from data bus 403), and can be further configured to compare the select value against the assigned value stored in 420. If there is a match signifying that serial module 410 is to be accessed, then select/assign controller 418 can cause register 432 to generate a serial selected signal via path 413, thereby indicating to other elements (e.g., circuitry), such as memory support circuits 419a, which can include write circuits (e.g., write buffers, page buffers, etc.), read circuits, charge pump circuits, write signal slew rate control circuits, or other memory-related circuits, that serial module 410 is operating in serial mode.

To illustrate the operation of serial modules 410 and 460, consider the following examples in which serial modules 410 and 460 operate in assignment mode and run mode. Initially, serial modules 410 and 460 each can be unassigned. When unassigned, memory 420 and memory 479 can be unprogrammed, and register 422 and register 472 can be in an unprogrammed state specifying that the serial modules are unassigned. For example, register 422 and register 472 can include data representing a logical “1”, such that an assigned* signal (as an active low signal) via path 424 can be transmitted to another serial module to disable serial mode operation (e.g., to place the recipient serial module in radial or parallel mode). Consider that terminal 411a is grounded, thereby enabling select/assign controller 418 to assign serial module 410, whereas terminal 411b is coupled to register 422 to receive an assigned* signal that disables select/assign controller 468, thereby placing serial module 460 in a mode in which it will not respond in run mode to memory-access related signals (e.g., write and read signals) from group 401. Similarly, register 472 can be in a state that disables another serial module (not shown).

To assign serial module 410 during an assignment mode, an identifier “00” (to identify serial module 410 for accessing memory 441a) can be placed onto data bus 403 and an assignment/selection command (e.g., to operate select/assign controller 418 to operate in assignment mode) can be placed onto address bus 404. In some cases, chip select signal line 405 can include a signal that enables operation of select/assign controller 418, and a signal can be applied to write signal line 406 that causes a write operation with respect to memory 420. In particular, the value 00 can be programmed into memory 420. After memory 420 is programmed, serial module 410 can be considered to be “assigned,” and select/assign controller 418 can set register 422 to indicate that serial module 410 has been assigned (e.g., with a logical “0”). The value of logical “0” can propagate via path 424 to terminal 411b, thereby enabling select/assign controller 468 to operate in assignment mode during a subsequent assignment operation. To assign serial module 460, an identifier “01” (to identify serial module 460 for accessing memory 441b) can be placed onto data bus 403 and an assignment/selection command (e.g., to operate select/assign controller 468 to operate in assignment mode) can be placed onto address bus 404. Chip select signal line 405 can include a signal that enables operation of select/assign controller 468, and a signal can be applied to write signal line 406 that causes a write operation with respect to memory 479. In particular, the value “01” is programmed into memory 479. Note that select/assign controller 418 can also receive signal from group 401, but can place register 422 in a state indicating that serial module 460 has been assigned. Thus, serial module 410 can ignore signals in group 401 when an assignment/selection command is present on address bus 404. Also, other serial modules (not shown) receive a logical “1” via terminals, similar to terminals 411a and 411b, from other unassigned serial modules. Therefore, serial module 460 can be the only one selected for performing an assignment or selection operation, according to some embodiments. After memory 479 is programmed, serial module 460 can be considered to be “assigned,” and select/assign controller 468 can set register 472 to indicate that serial module 460 has been assigned (e.g., with a logical “0”). In some embodiments, memory arrays, such as memory arrays 441a and 441b, can be sequentially placed into assignment mode by sequentially propagating the assigned* signal that places a serial module in serial mode while placing the other serial modules in parallel, thereby blocking the programming of assignment values in serial modules other than the one in serial mode. After serial modules for the memory arrays have been assigned, the serial modules can operate in serial mode.

Next, consider the following examples to illustrate the selection of serial modules 410 and 460 to operate in run mode. To select serial module 460 to perform memory operations during run mode, consider that select/assign controller 468 can determine that serial module 460 has been assigned (e.g., by examining the contents of register 472), thereby indicating that the assignment/selection command causes serial module 460 to operate in serial mode to perform memory operations. To select serial module 460 to operate in run mode, a select value “01” (to identify serial module 460 for accessing memory 441b) can be placed onto data bus 403 and an assignment/selection command (e.g., to operate select/assign controller 468 to operate in run mode) can be placed onto address bus 404. Select/assign controller 468 can operate to compare the select value of “01” against the value (e.g., “01”) stored in register 472. Upon determining a match, select/assign controller 468 can cause register 480 to set to a state indicating that serial module 460 is in run mode. Note that a comparison by select/assign controller 418 between “01” (on data bus 403) and “00” (stored in memory 420) will not determine a match, thereby causing register 432 to indicate that serial module 410 is unselected (e.g., not in serial mode). After serial module 460 is selected, memory array 441b can be accessed in response to the addresses and control lines of group 401 to produce the desired functions when chip select signal line 405 becomes active. In run mode, serial module 460 can be configured to receive address bits representing an address (or portions thereof) can be placed onto address bus 404, and data bus 403 can be configured to carry write data to a memory array or read data from a memory array. Thus, serial module 460 can be configured to perform write and read operations when selected. In some cases, a group of least significant eight bits can be placed onto address bus 404 during one part of a memory access operation (e.g., a write or read operation) and another group of eight bits can be placed onto address but 404 during another part of the memory access operation. As long as serial module 460 is selected, register 480 can generate a serial selected signal on path 413b to enable other circuitry, such as memory support circuits 419b (e.g., write and read circuitry), to access memory array 441b.

Further to the example serial module 460 operating in run mode, consider that serial module 410 is to be accessed next. To initiate the selection, an assignment/selection command can be inserted onto address bus 404 and the select value of “00” can be placed onto data bus 403. In this cases, select/assign controller 468 can detect a mismatch between the select value and the value stored in memory 479, thereby deselecting serial module 460, whereas select/assign controller 418 can detect a match between the select value and the value store in memory 420, thereby selecting serial module 410. Thereafter, memory support circuits 419a, which can include write circuits (e.g., write buffers, page buffers, etc.), read circuits, charge pump circuits, write signal slew rate control circuits, or other memory-related circuits, can operate in association with memory array 441a.

FIGS. 4B and 4C depict an interface implemented in multiple layers of memory in accordance with various embodiments of the invention. FIG. 4B depicts an interface 473 implemented in a memory device 475, according to some embodiments. As shown, multiple layers of memory, including memory array layers 477, 478 and 485, can be formed directly on top of a logic layer 488, which, in turn, can be formed in a semiconductor substrate. In some embodiments, memory array layers 477, 478 and 485 can be composed of two terminal memory devices. Interface 473 can include a mode module 487 for implementing parallel or serial modes of memory access as described above, a controller 486 that can control operation of memory accesses (e.g., a processor or other logic, including DMA logic), and a serial module 476. Further, serial module 476 can include a selection module decoder 483 and a lock module decoder 484 formed in logic layer 477 (e.g., fabricated FEOL) whereas a selection module memory 481 and a lock module memory 482 can be implemented using one of memory array layers 477, 478 and 485 (e.g., BEOL memory layers). Note that selection module decoder 483 and selection module memory 481 can constitute selection module 210 of FIG. 2, and lock module decoder 484 and lock module memory 482 can constitute lock module 204.

FIG. 4C is a diagram 450 depicting a perspective view of memory device 475 of FIG. 4B. As shown, selection module memory 462 can be implemented in a portion 454 of multiple layers of memory 452, and lock module memory 464 can be implemented in portions 456 and 458 of multiple layers of memory 452. Logic plane 460 (or logic layer) can include controller logic 466, mode module logic 468, and serial module logic 470. As shown, multiple layers of memory 452 can be formed on logic plane 460.

In FIG. 4C, the logic plane 497 can be a silicon wafer upon which active circuitry (e.g., CMOS devices) for performing data operations (e.g., read and write operations in serial mode or parallel mode) on the one or more layers of memory 490 (e.g., the array layers 492, 492a, 493, 494). The logic plane 497 and its associated circuitry are fabricated on the wafer as part of a front-end-of-the-line (FEOL) fabrication process. The one or more layers of memory 490 are fabricated on top of the logic plane 497 as part of a back-end-of-the-line (BEOL) fabrication process. Although the BEOL memory layers 490 and the FEOL logic plane 497 are depicted as being physically separate, that depiction is for purposes of explanation only and in fact, the BEOL memory layers 490 are in contact with one another and are vertically stacked upon one another and are fabricated directly above the logic plane 497 and are in contact with the logic plane 497 (see FIG. 4B) such that the BEOL memory layers 490 and the logic plane 497 comprise different portions of the same die. For example, the die can be cut (e.g., singulated) from a silicon wafer and the die comprises the FEOL portion that is fabricated first and the BEOL portion that is fabricated second and directly on top of the FEOL portion such that die comprises a unitary whole that can be packaged in a suitable package for an IC. As another example, in FIG. 4B, memory device 475 can comprise a die with a FEOL portion in logic layer 488 as depicted in heavy black line with active circuitry 483, 484, 486, and 487, and BEOL memory portions 481, 482, 485, 478, and 477. The FEOL and BEOL processes can occur at the same or different fabrication facilities and the same or different vendors may perform the FEOL and BEOL processes. The active circuitry in logic plane 497 can include some or all of the non-memory related circuitry (e.g., not the one or more layers of memory 490) described herein, such as circuitry 496, 498, and 499 of FIG. 4C, or the circuitry depicted in FIGS. 1 through 6B, for example. The active circuitry in logic plane 497 can include circuits that are not related to data operations on the memory 490.

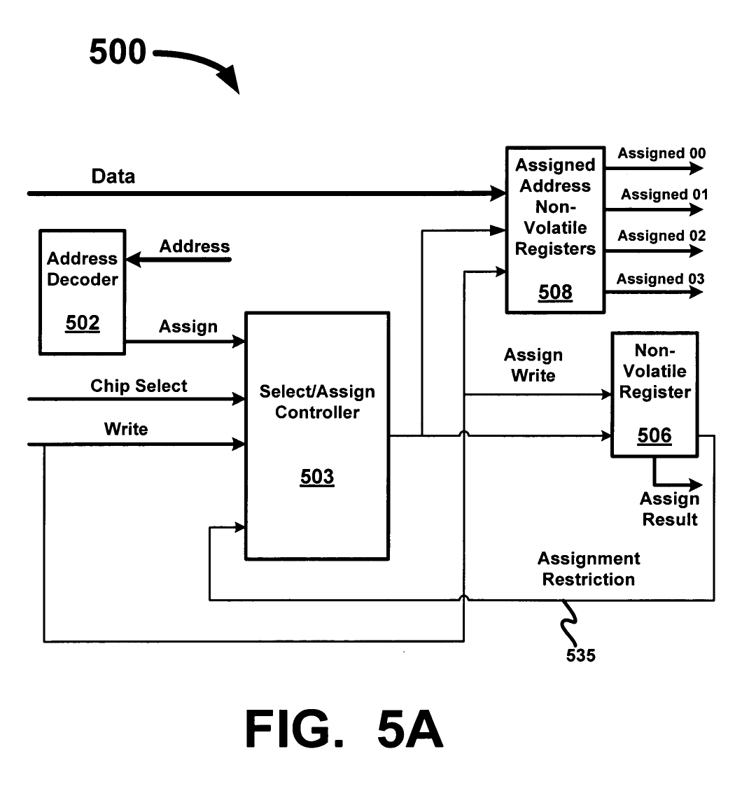

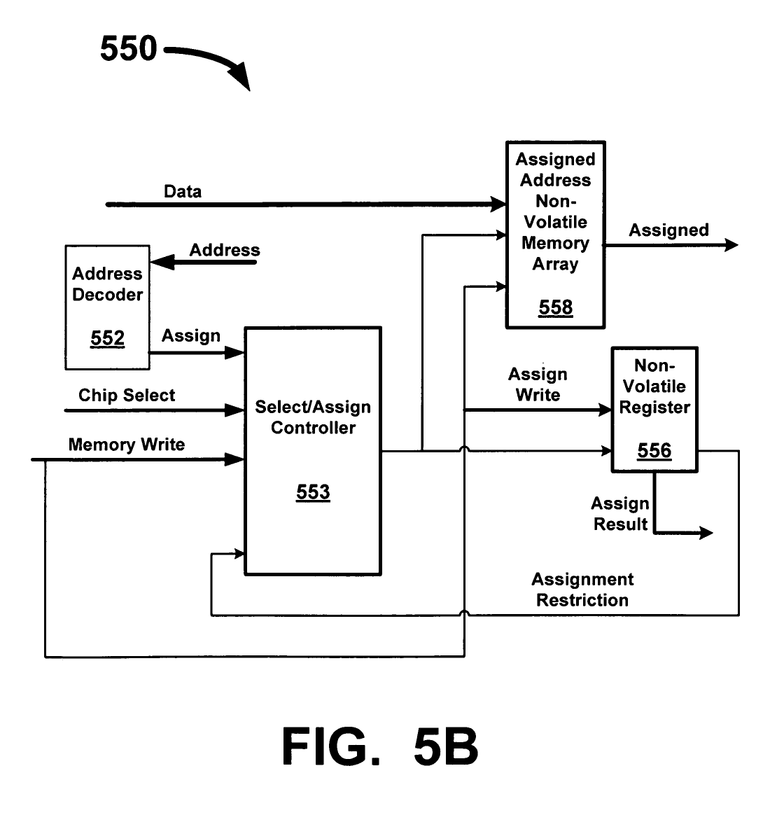

FIGS. 5A and 5B depict examples of logic for implementing assignment modes in accordance with various embodiments of the invention. FIG. 5A depicts a serial module 500 including an address decoder 502, a select/assign controller 503, a memory 508, and a register 506, which can have respective functionalities as an address decoder 414, a select/assign controller 418, memory 420, and register 422. Address decoder 502 can decode a command on an address bus to generate an “assign” signal, which can be applied to select/assign controller 503. In this example, memory 508 includes non-volatile third dimensional memory and includes address locations that each can set forth the identity of serial module 500. For example, the assignment value can be transmitted via the data bus and applied against memory 508. In this embodiment, the assignment value selects an address in memory 508 to be accessed. Then, select/assign controller 503 can program the address with an indicator for the serial module. For example, consider that the assignment value is 01, thereby causing address “01” to be accessed. Next, a logical “1” can be programmed at a memory location specified by address 01. Thereafter, a signal “assigned 01” can be generated, responsive to the value programmed in address “01”, to specify the identity of serial module 500. Other serial modules can be programmed at different addresses to distinguish those serial modules from serial module 500. Further, once memory 508 is programmed, serial module 500 is assigned. Select/assign controller 503 can be configured to store a state in register 506 that indicates serial module 500 is assigned. This state can be transmitted to another serial module. Further, register 506 can generate an “assignment restriction” signal via path 535 to disable select/assign controller 503 from performing subsequent assignment operations. In at least some embodiments, register 506 can be composed of non-volatile memory, such as third dimensional memory.

FIG. 5B depicts a serial module 550 including an address decoder 552, a select/assign controller 553, a memory 558, and a register 556, which can have respective functionalities as similarly-described elements, according to some embodiments. In this example, memory 558 can be configured to store an assignment value, and register 556 can store a state specifying whether serial module 550 has been assigned.

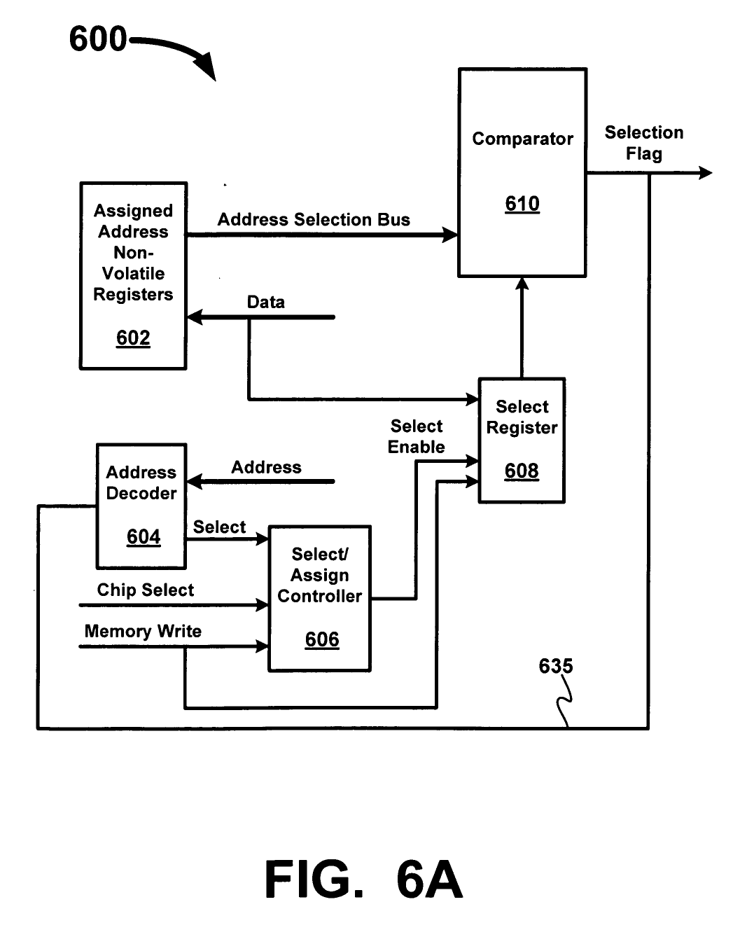

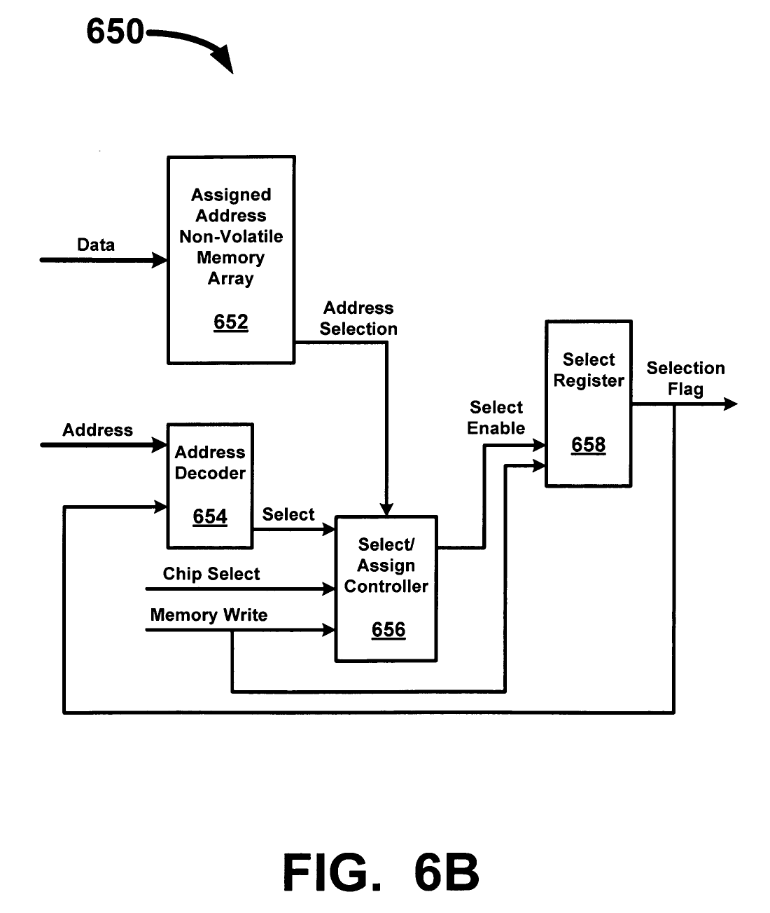

FIGS. 6A and 6B depict examples of logic for implementing selection of serial modules in accordance with various embodiments of the invention. FIG. 6A depicts a serial module 600 including an assigned address register 602, an address decoder 604, a select/assign controller 606, a select register 608, and a comparator 610. In some embodiments, comparator 601 and/or its functionality can reside within select/assign controller 606. In operation, address decoder 604 can receive an assignment/selection command via an address bus. The assignment/selection command can be decoded to generate a “select” signal, which is transmitted to select/assign controller 606. A select value can be transmitted to serial module 600 via a data bus. The select value can be loaded into register 608. Then, the assigned value, which has been previously programmed in an assignment mode, can be transmitted from register 602 to comparator 601, which can compare the select value from register 608 to the assigned value from 602. If comparator 601 determines a match, then a selection flag can be set specifying that serial module 600 has been selected. The state of the selection flag can be passed along path 635 to address decoder 604 to maintain selection of serial module 600.

FIG. 6B depicts a serial module 650 including an address decoder 654, a select/assign controller 656, a memory 652, and a select register 658. In this example, memory 652 can be configured to store an assignment value, and register 658 can store a state specifying whether serial module 650 has been assigned. It should be noted that the select register 658 can be made from non-volatile memory or a non-volatile register to allow power cycling with the memory powering on if it was last selected.

In FIGS. 4A-6B, the non-volatile registers, registers, buffers, memory, and memory array(s) can be BEOL memory as described above. Whereas, the circuitry described in FIGS. 4A-6B can be FEOL circuitry in a logic layer or plane that is fabricated on a substrate, such as a silicon wafer, for example. In some implementations, the registers and/or buffers can be a dedicated or memory mapped portion of memory array or can be implemented as one or more partitions of a memory array.

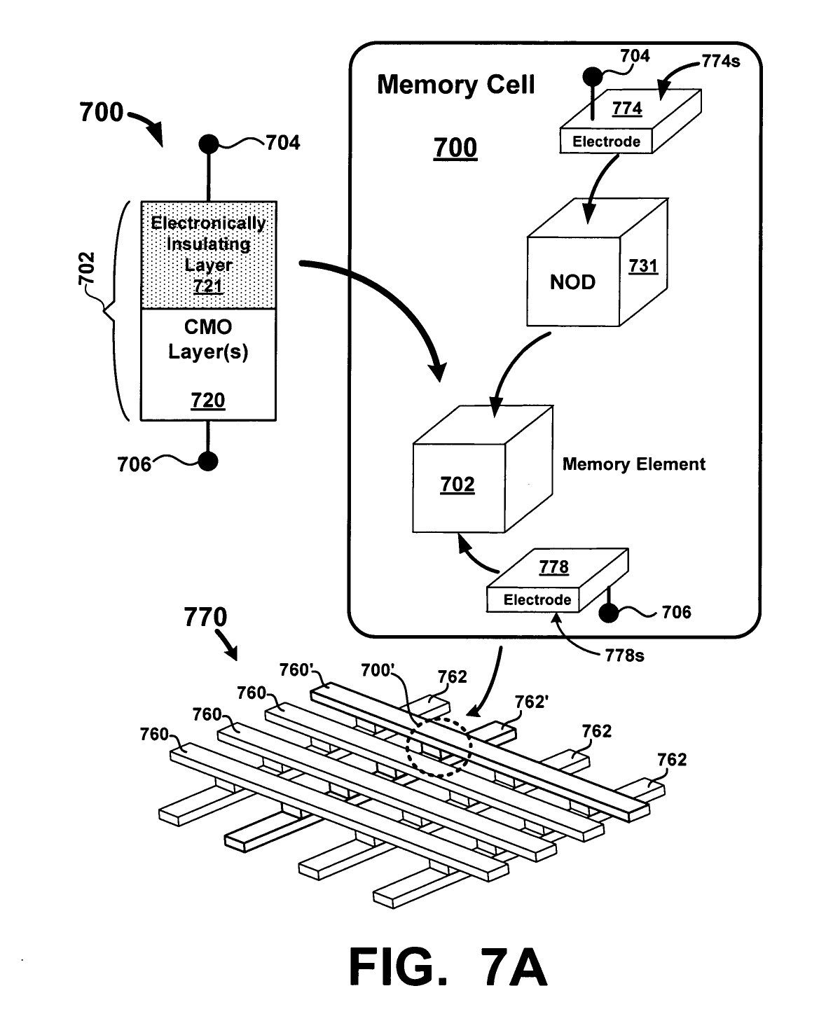

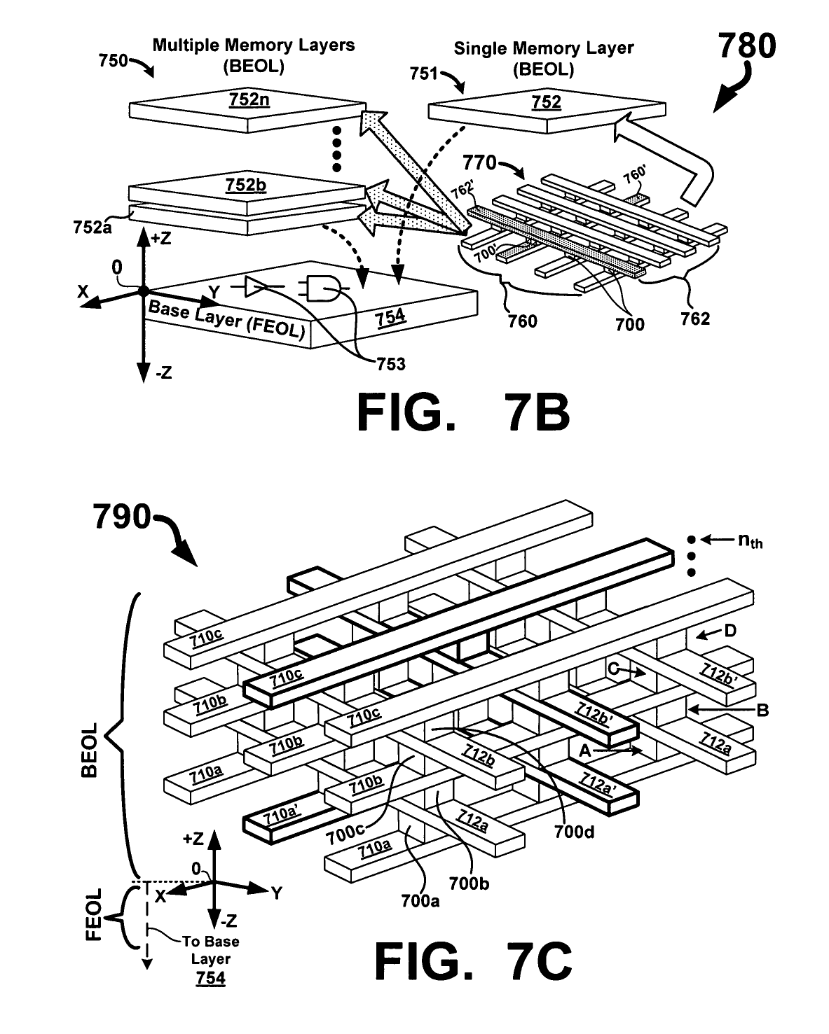

FIG. 7A depicts an example of arrayed memory cells according to various embodiments of the invention. In this example, a memory cell 700 includes a memory element 702 and NOD 731 positioned above or below (not shown) the memory element 702. The NOD 731 is optional and some configurations of the memory cell 700 will not use the NOD 731. The memory element 702 can include the above mentioned CMO layer(s) and electronically insulating layer (e.g., a thin film layer YSZ having a thickness of approximately 50 Å or less) denoted as 720 and 721 respectively. The layers 720 and 721 can be discrete layers as depicted or they can be continuous and un-etched layers (not shown). Memory cell 700 further includes terminals 704 and 706 with the memory element 702 electrically in series with the terminals (704, 706). Terminals 704 and 706 can be electrically coupled with or can be formed as electrodes 774 and 778. The electrodes (774, 778) can be made from an electrically conductive material including, but not limited to, platinum (Pt), gold (Au), silver (Ag), iridium (Ir), iridium oxide (IrO_{X}), ruthenium (Ru), palladium (Pd), aluminum (Al), alloys of those materials, and the like. The electrodes (774, 778) can be in contact with and/or electrically coupled with conductive array lines operative to apply the aforementioned voltages for data operations, such as read voltages and write voltages (e.g., program and erase voltages) across one or more selected memory cells 700. The memory element 702 and NOD 731 are electrically in series with each other and electrically in series with the electrodes (774, 778).

Memory cell 700 can be formed between conductive array lines, such as array lines 762 and 760. Thus, memory cell 700 can be formed in an array of other memory cells 700. In FIG. 7A, array lines 762′ and 760′ are depicted in heavy line to illustrate that those array lines have voltages for data operations applied to them such that memory cell 700′ is the selected memory cell for the data operation. The array can be a cross-point array 770 including groups of conductive array lines 760 and 762. For example, array lines 760 can be electrically coupled with the electrodes 774 of the memory cells 700 and/or may be in contact with a surface 774s of the electrodes 774, and array lines 762 can be electrically coupled with the electrodes 778 of the memory cells 700 and/or may be in contact with a surface 778s of the electrodes 778. Although not depicted in FIG. 7A, the active circuitry that applies the voltages for data operations is positioned below the array 770 on a substrate (e.g., FEOL logic layer 488 or 497) with the array 770 fabricated directly on top of the substrate and the array 770 in contact with the substrate.

FIG. 7B depicts an integrated circuit including memory cells disposed in a single layer or in multiple layers of memory, according to various embodiments of the invention. In this example, integrated circuit 780 is shown to include either multiple layers 750 of memory (e.g., layers 752a, 752b, . . . 752n) or a single memory layer 751 (e.g., layer 752) formed on a base layer 754 with the base layer 754 serving as the logic layer (e.g., logic layers 488 or 497) for the array(s) fabricated above it. As will be described in greater detail below, the layers 754 and 752a, 752b, . . . 752n or layers 754 and 752 are not physically separate layers as depicted in FIG. 7B for purposes of illustration, rather they are different portions of a unitary die 800 (not shown) comprised of a FEOL portion for the base layer 754 and a BEOL portion for the layer 752 or layers 752a, 752b, . . . 752n. In at least some embodiments, each layer (e.g., layer 752 or layers 752a, 752b, . . . 752n) of memory can be a cross-point memory array 770 including conductive array lines 760 and 762 arranged in different directions (e.g., orthogonal to each other) to access re-writable memory cells 700 such as two-terminal memory cells as described above. Layer 752 or layers 752a, 752b, . . . 752n can be used to implement the above mentioned memory planes/layers, non-volatile registers, processor memory, data memory, and the like. Examples of conductive array lines include X-line conductive array lines (e.g., 760) and Y-line conductive array lines (e.g., 762). The X and Y conductive array lines are sometimes referred to as row lines and column lines respectively. Base layer 754 can include a bulk semiconductor substrate (e.g., a silicon wafer) upon which memory access circuits 753 for performing data operations (e.g., read operations and write operations including the writing copy data) on the memory cells 700 in memory 750 or 751 are fabricated. Base layer 754 may include other circuitry that may or may not be related to data operations on memory. Base layer 754 and circuitry 753 (e.g., CMOS active circuitry such as decoders, drivers, sense amps, buffer, registers, controller, processor, mode module, serial module, selection module, lock module, etc.) can be formed in a front-end-of-the-line (FEOL) fabrication process and multiple memory layers 750 or single memory layer 751 can be formed in a back-end-of-the-line (BEOL) fabrication process tailored to fabricating layer(s) of memory arrays on top of the base layer 754. Although not depicted, the base layer 754 can include an inter-level interconnect structure configured to include nodes (e.g., openings in a dielectric material or electrically conductive structures such as vias, plugs, thrus, damascene structures, etc.) for facilitating electrical coupling between the circuitry 753 and the conductive array lines (760, 762) of the array(s) so that signals (e.g., read and write voltages) for data operations (e.g., read and write operations) are electrically communicated between the array(s) and the circuitry 753. The inter-level interconnect structure can be one of the last microelectronic structures fabricated during the FEOL processing.

Moving on to FIG. 7C, where a vertically stacked array 790 includes a plurality of memory layers A, B, C, and D with each memory layer including memory cells 700a, 700b, 700c, and 700d. Although only four layers are depicted, the array 790 can include fewer layers or can include additional layers up to an nth layer. The array 790 includes three levels of x-direction conductive array lines 710a, 710b, and 710c, and two levels of y-direction conductive array lines 712a, and 712b. Unlike the configuration for array 770 in FIG. 7A, the memory cells 700a, 700b, 700c, and 700d depicted in FIG. 7C share conductive array lines with other memory cells that are positioned above, below, or both above and below that memory cell. The conductive array lines, the memory cells, dielectric materials that electrically isolate structures in the array 790 (not shown), and other structures in the array 790 are formed BEOL above the base layer 754 (not shown) as indicated by +Z on the Z-axis above the dashed line at origin 0; whereas, the active circuitry for performing data operations on the array 790 and the interconnect structure for electrically coupling the active circuitry with the array 790 (e.g., the conductive array lines) are previously formed FEOL as indicated by −Z on the Z-axis below the dashed line at origin 0. Accordingly, the BEOL structure for array 790 is formed on top of the FEOL structure for base layer 754 with the order of fabrication going in a direction from −Z (i.e., FEOL) to +Z (i.e., BEOL) along the Z-axis.

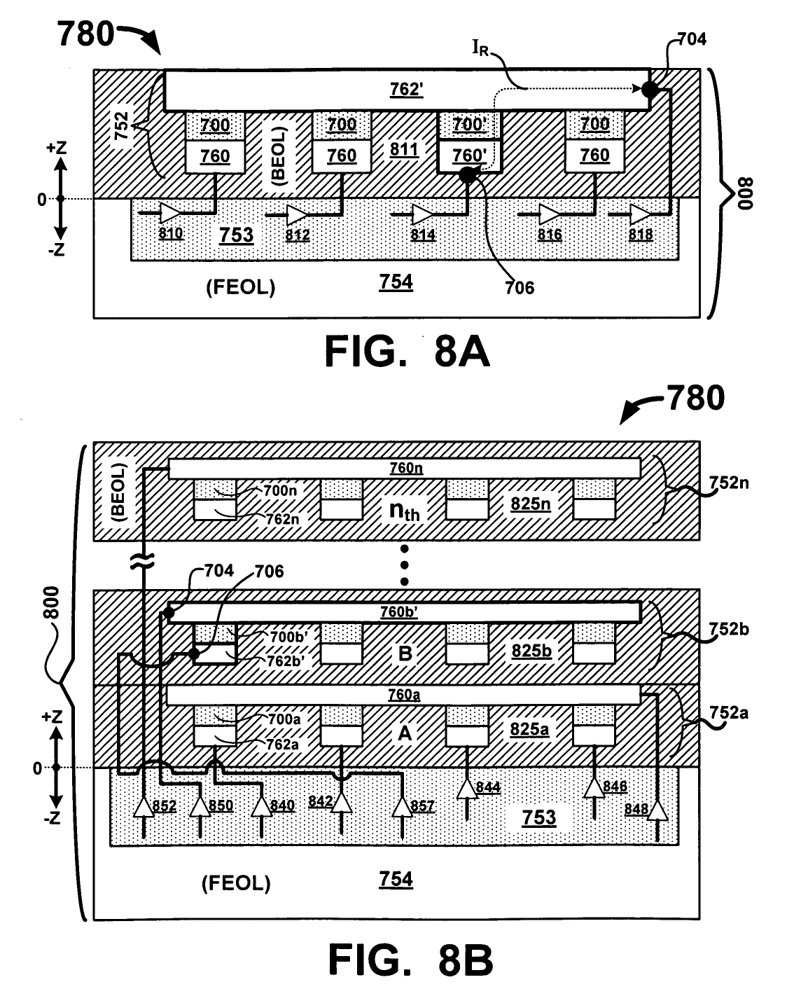

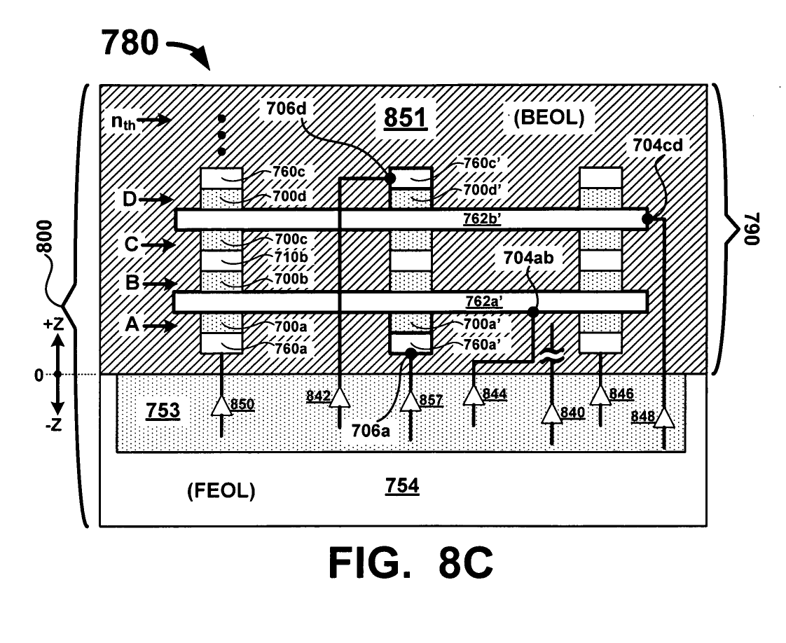

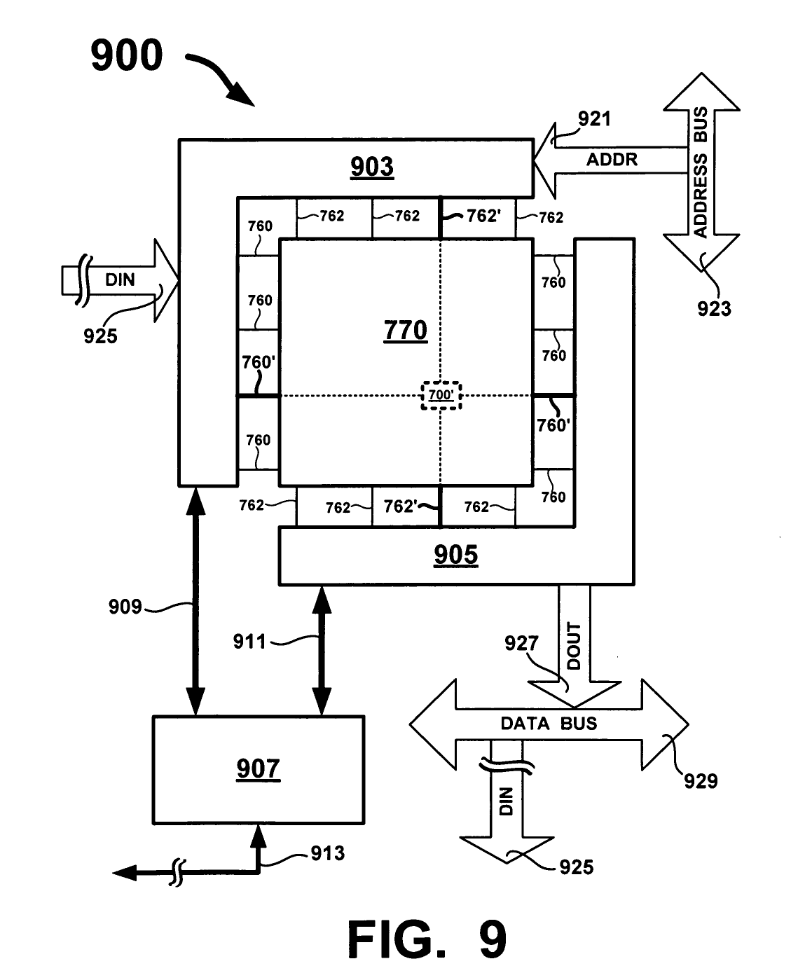

Reference is now made to FIG. 8A, where integrated circuit 780 includes the base layer 754 and active circuitry 753 fabricated on the base layer 754 (e.g., a silicon Si wafer). The integrated circuit 780 is comprised of a single unitary die 800 having a first portion (i.e., the base layer 754) fabricated first using FEOL processing and a second portion (i.e., the single memory layer 752) fabricated second and formed directly on top of the base layer 754 using BEOL processing, such that the second portion is integrally formed with the first portion and completes the formation of the die 800. As one example, the base layer 754 can be a silicon (Si) wafer and the active circuitry 753 can be microelectronic devices formed on the base layer 754 using a CMOS fabrication process. The memory cells 700 and their respective conductive array lines (760, 762) can be fabricated on top of the active circuitry 754 in the base layer 754. Those skilled in the art will appreciate that an inter-level interconnect structure (not shown) can electrically couple the conductive array lines (760, 762) with the active circuitry 753 which may include several metal layers. For example, vias can be used to electrically couple the conductive array lines (760, 762) with the active circuitry 753. The active circuitry 753 may include but is not limited to address decoders, sense amps, memory controllers, data buffers, direct memory access (DMA) circuits, voltage sources for generating the read and write voltages, mode modules, serial modules, selection modules, lock modules controllers, processors, just to name a few. Active circuits 810-818 can be configured to apply the select voltage potentials (e.g., read and write voltage potentials) to selected conductive array lines (760′, 762′). Moreover, the active circuitry 753 may be electrically coupled with the conductive array lines (760′, 762′) to sense a read current I_{R} that flows through selected memory cells 700′ during a read operation and the read current I_{R} can be sensed and processed by the active circuitry 753 to determine the conductivity profiles (e.g., the resistive state) of the selected memory cells 300′. Examples of conductivity profiles include but are not limited to a programmed conductivity profile written to a memory cell 700′ during a programming data operation and an erased conductivity profile written to a memory cell 700′ during an erase data operation. Memory cells 700 can store data as a plurality of conductivity profiles that can include the programmed or erased conductivity profiles only (e.g., only 1-Bit of data stored per memory cell 700) or more than two conductivity profiles for storing multiple bits of data per memory cell 700 (e.g., two or more bits of data per memory cell 700). The direction of current flow for the read current I_{R} will depend on a magnitude and polarity of a read voltage applied across terminals 704 and 706. In some applications, it may be desirable to prevent un-selected array lines (760, 762) from floating. The active circuits 753 can be configured to apply an un-select voltage potential (e.g., approximately a ground potential) to the un-selected array lines (760, 762). A dielectric material 811 (e.g., SiO₂) may be used where necessary to provide electrical insulation between elements of the integrated circuit 780.

Moving now to FIG. 8B, an integrated circuit 780 includes a plurality of non-volatile memory arrays that are vertically stacked above one another (e.g., along a +Z axis) and are positioned above the base layer 754 that includes the active circuitry 753. The integrated circuit 780 includes vertically stacked memory layers A and B and may include additional memory layers up to an nth memory layer. The memory layers A, B, . . . through the nth layer can be electrically coupled with the active circuitry 753 in the base layer 754 by an inter-level interconnect structure as was described above. Layer A includes memory cells 700a and first and second conductive array lines (760a, 762a), Layer B includes memory cells 700b and first and second conductive array lines (760b, 762b), and if the nth layer is implemented, then the nth layer includes memory cells 700n and first and second conductive array lines (760n, 762n). Dielectric materials 825a, 825b, and 825n (e.g., SiO₂) may be used where necessary to provide electrical insulation between elements of the integrated circuit 820. Active circuits 840-857 can be configured to apply the select voltage potentials (e.g., read and write voltage potentials) to selected conductive array lines (e.g., 760a, b, . . . n, and 762a, b, . . . n). Driver circuits 850 and 857 are activated to select conductive array lines 760′ and 762′ to select memory cell 700b′ for a data operation. As was described above, the active circuits 753 can be used to sense the read current I_{R} (not shown) from selected memory cells 700b′ during a read operation and can be configured to apply the un-select voltage potential to the un-selected array lines. As described above, the integrated circuit 780 comprises the die 800 that is a unitary whole comprised of a FEOL circuitry portion fabricated on base layer 754 and a BEOL memory portion having multiple memory layers that is in contact with the FEOL portion and is fabricated directly on top of the FEOL portion.

In FIG. 8C, an integrated circuit 780 includes base layer 754, active circuitry 753, and vertically staked memory layers A, B, C, and D that are fabricated above the base layer 754. Active circuits 840-857 are configured to perform data operations on the vertically staked memory layers A, B, C, and D. Driver circuits 844 and 857 are activated to select memory cell 700a′ for a data operation and driver circuits 842 and 848 are activated to select memory cell 700d′ for a data operation. A dielectric layer 851 is operative to electrically isolate the various components of integrated circuit 780. As described above, the integrated circuit 780 comprises the die 800 that is a unitary whole comprised of a FEOL circuitry portion fabricated on base layer 754 and a BEOL memory portion having multiple memory layers that is in contact with the FEOL portion and is fabricated directly on top of the FEOL portion.

Moving on to FIG. 9, an exemplary memory system 900 includes the aforementioned non-volatile two-terminal cross-point memory array 770 (array 770 hereinafter) and the plurality of first conductive and second conductive traces denoted as 760 and 762, respectively. The memory system 900 also includes an address unit 903 and a sense unit 905. The address unit 903 receives an address ADDR, decodes the address, and based on the address, selects at least one of the plurality of first conductive traces (denoted as 760′) and one of the plurality of second conductive traces (denoted as 762′). The address unit 903 applies select voltage potentials (e.g., read or write voltages) to the selected first and second conductive traces 760′ and 762′. The address unit 903 also applies a non-select voltage potential to unselected traces 760 and 762. The sense unit 905 senses one or more currents flowing through one or more of the conductive traces. During a read operation to the array 770, current sensed by the sense unit 905 is indicative of stored data in a memory cell 700′ positioned at an intersection of the selected first and second conductive traces 760′ and 762′. A bus 921 coupled with an address bus 923 can be used to communicate the address ADDR to the address unit 903. The sense unit 905 processes the one or more currents and at least one additional signal to generate a data signal DOUT that is indicative of the stored data in the memory cell. In some embodiments, the sense unit 905 may sense current flowing through a plurality of memory cells and processes those currents along with additional signals to generate a data signal DOUT for each of the plurality of memory cells. A bus 927 communicates the data signal DOUT to a data bus 929. During a write operation to the array 770, the address unit 903 receives write data DIN to be written to a memory cell specified by the address ADDR. A bus 925 communicates the write data DIN from the data bus 929 to the address unit 903. The address unit 903 determines a magnitude and polarity of the select voltage potentials to be applied to the selected first and second conductive traces 760′ and 762′ based on the value of the write data DIN. For example, one magnitude and polarity can be used to write a logic “0” and a second magnitude and polarity can be used to write a logic “1”. In other embodiments, the memory system 900 can include dedicated circuitry that is separate from the address unit 903 to generate the select potentials and to determine the magnitude and polarity of the select potentials.

One skilled in the art will appreciate that the memory system 900 and its components (e.g., 903 and 905) can be electrically coupled with and controlled by an external system or device (e.g., a microprocessor or a memory controller). Optionally, the memory system 900 can include at least one control unit 907 operative to coordinate and control operation of the address and sense units 903 and 905 and any other circuitry necessary for data operations (e.g., read and write operations) to the array 770. Although only one array 770 is depicted, the array 770 can comprise a single layer of memory (e.g., 752) or multiple layers of vertically stacked memory (752a, 752b, . . . 752n) as depicted in FIGS. 7A-8C. One or more signal lines 909 and 911 can electrically couple the control unit 907 with the address and sense units 903 and 905. The control unit 907 can be electrically coupled with an external system (e.g., a microprocessor or a memory controller) through one or more signal lines 913. Here, control unit 907 can implement some or all of the FEOL circuitry described above in reference to FIGS. 1-6B.

As was described above in reference to FIGS. 7A through 8C, one or more of the arrays 770 can be positioned over a substrate 754 that includes active circuitry 753 and the active circuitry 753 can be electrically coupled with the array(s) 770 using an interconnect structure that couples signals from the active circuitry 753 with the conductive array lines 760 and 762. In FIG. 9, the busses, signal lines, control signals, the address, sense, and control units 903, 905, and 907 can comprise the active circuitry 753 and its related interconnect, and can be fabricated FEOL on the substrate 754 (e.g., a silicon wafer) using a microelectronics fabrication technology, such as CMOS, for example. The circuitry, busses, and control signals depicted in FIG. 9 can implement the aforementioned compress engine and associated circuitry (e.g., FEOL circuitry in the logic layers depicted in FIGS. 1 and 4B-4C) and the array 770 can be used to implement the one or more memory layers (e.g., BEOL memory planes in FIGS. 1, 4A and 4B).

Although FIGS. 7B and 8A depict single layer arrays, the BEOL memory can be configured to have a plurality of separate arrays on a single plane with some of the plurality of arrays used for the data area and other arrays used for non-volatile registers, selection module memory, and lock module memory. In this configuration, the arrays for the data area and the copy area are disposed on the same memory plane in horizontal relationship to one another (see FIG. 3C). Therefore, the configurations depicted in FIGS. 1, 2, and 4A-6B need not be restricted to vertical only configurations. The BEOL memory can be flexibly configured into horizontal only configurations, vertically stacked configurations (e.g., FIGS. 1 and 4B-4C), or a combination of both horizontal and vertical configurations (e.g., FIG. 4B). In some applications, one or more arrays can be partitioned such that some portions of the array are used for data, other portions are used for a non-volatile register, and yet other portions are used for the selection module memory and/or the lock module memory.

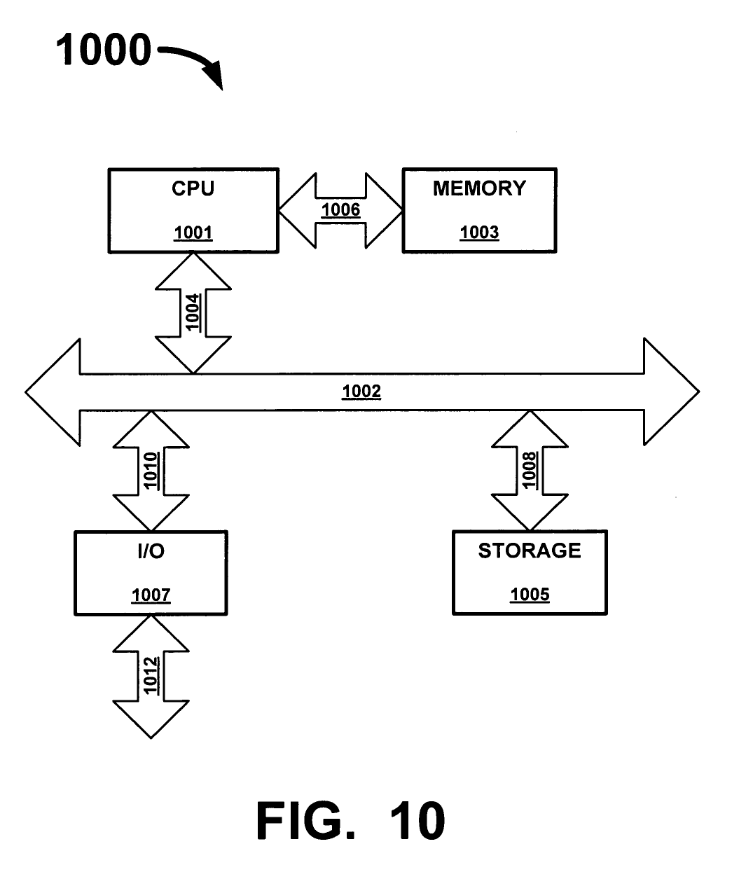

Reference is now made to FIG. 10, where an electrical system 1000 includes a CPU 1001 that is electrically coupled 1004 with a bus 1002, an I/O unit 1007 that is electrically coupled 1010 with the bus 1002, and a storage unit 1005 that is electrically coupled 1008 with the bus 1002. The I/O unit 1007 is electrically coupled 1012 to external sources (not shown) of input data and output data. The CPU 1001 can be any type of processing unit including but not limited to a microprocessor (μP), a micro-controller (μC), and a digital signal processor (DSP), for example. Via the bus 1002, the CPU 1001, and optionally the I/O unit 1007, performs data operations (e.g., reading and writing data) on the storage unit 1005. The storage unit 1005 stores at least a portion of the data in the aforementioned non-volatile two-terminal cross-point array as depicted in FIGS. 7A through 8C. Each memory array includes a plurality of the two-terminal memory cells 700. The configuration of the storage unit 1005 will be application specific. Example configurations include but are not limited to one or more single layer non-volatile two-terminal cross-point arrays (e.g., 752) and one or more vertically stacked non-volatile two-terminal cross-point arrays (e.g., 752a-752n). In the electrical system 1000, data stored in the storage unit 1005 is retained in the absence of electrical power. The CPU 1001 may include a memory controller (not shown) for controlling data operations to the storage unit 1005.

Alternatively, the electrical system 1000 may include the CPU 1001 and the I/O unit 1007 coupled with the bus 1002, and a memory unit 1003 that is directly coupled 1006 with the CPU 1001. The memory unit 1003 is configured to serve some or all of the memory needs of the CPU 1001. The CPU 1001, and optionally the I/O unit 1007, executes data operations (e.g., reading and writing data) to the non-volatile memory unit 1003. The memory unit 1003 stores at least a portion of the data in the aforementioned non-volatile two-terminal cross-point array as depicted in FIGS. 7A through 8C. Each memory array can include a plurality of the two-terminal memory cells 700 with each memory cell 700 including the two-terminal memory element 702 and NOD 731. The configuration of the memory unit 1003 will be application specific. Example configurations include but are not limited to one or more single layer non-volatile two-terminal cross-point arrays (e.g., 752) and one or more vertically stacked non-volatile two-terminal cross-point arrays (e.g., 752a-752n). In the electrical system 1000, data stored in the memory unit 1003 is retained in the absence of electrical power. Data and program instructions for use by the CPU 1001 may be stored in the memory unit 1003. The CPU 1001 may include a memory controller (not shown) for controlling data operations to the non-volatile memory unit 1003. The memory controller may be configured for direct memory access (DMA). Storage 1005 and/or non-volatile memory unit 1003 can include the aforementioned compress engine and associated circuitry (e.g., FEOL circuitry in FIGS. 1A-6) for implementing data compression as described herein.

Reference is now made to FIG. 11, where a top plan view depicts a single wafer (denoted as 1170 and 1170′) at two different stages of fabrication: FEOL processing on the wafer denoted as 1170 during the FEOL stage of processing where active circuitry 753 is formed; followed by BEOL processing on the same wafer denoted as 1170′ during the BEOL stage of processing where one or more layers of non-volatile memory are formed. Wafer 1170 includes a plurality of the base layer die 754 (see 488 and 497 in FIGS. 4B and 4C respectively) formed individually on wafer 1170 as part of the FEOL process. As part of the FEOL processing, the base layer die 754 may be tested 1172 to determine their electrical characteristics, functionality, performance grading, etc. After all FEOL processes have been completed, the wafer 1170 is optionally transported 1104 for subsequent BEOL processing (e.g., adding one or more layers of memory such as single layer 752 or multiple layers 752a, 752b, . . . 752n) directly on top of each base layer die 754. A base layer die 754 is depicted in cross-sectional view along a dashed line FF-FF where the substrate the die 754 is fabricated on (e.g., a silicon Si wafer) and its associated active circuitry are positioned along the −Z axis. For example, the one or more layers of memory are grown directly on top of an upper surface 754s of each base layer die 754 as part of the subsequent BEOL processing.

During BEOL processing the wafer 1170 is denoted as wafer 1170′, which is the same wafer subjected to additional processing to fabricate the memory layer(s) directly on top of the base layer die 754. Base layer die 754 that failed testing may be identified either visually (e.g., by marking) or electronically (e.g., in a file, database, email, etc.) and communicated to the BEOL fabricator and/or fabrication facility. Similarly, performance graded base layer die 754 (e.g., graded as to frequency of operation) may identified and communicated to BEOL the fabricator and/or fabrication facility. In some applications the FEOL and BEOL processing can be done by the same fabricator or performed at the same fabrication facility. Accordingly, the transport 1104 may not be necessary and the wafer 1170 can continue to be processed as the wafer 1170′. The BEOL process forms the aforementioned memory layer(s) directly on top of the base layer die 754 to form a finished die 800 that includes the FEOL circuitry portion 754 along the −Z axis and the BEOL memory portion along the +Z axis (see FIGS. 7B-8C). A cross-sectional view along a dashed line BB-BB depicts a memory device die 800 with a single layer of memory 752 grown directly on top of base die 754 along the +Z axis, and alternatively, another memory device die 800 with three vertically stacked layers of memory 752a, 752b, and 752c grown directly on top of base die 754 along the +Z. Finished die 800 on wafer 1170′ may be tested 1174 and good and/or bad die identified. Subsequently, the wafer 1170′ can be singulated 1178 to remove die 800 (e.g., die 800 are precision cut or sawed from wafer 1170′) to form individual memory device die 800. The singulated die 800 may subsequently be packaged 1179 to form integrated circuits 1190 for mounting to a PC board or the like, as a component in an electrical system (not shown). Here a package 1181 can include an interconnect structure 1187 (e.g., pins, solder balls, or solder bumps) and the die 800 mounted in the package 1181 and electrically coupled 1183 with the interconnect structure 1187 (e.g., using wire bonding). The integrated circuits 1190 (IC 1190 hereinafter) may undergo additional testing 1185 to ensure functionality and yield. One or more of the IC's 1190 can be used in a data storage system (e.g., a RAID storage system) in which the non-volatile memory in the one or more layers of memory in each IC 1190 is used to replace or supplant HDD's in the RAID system. Unlike FLASH non-volatile memory, the IC's 1190 do not require an erase operation prior to a write operation so the latency associated with the erase operation is eliminated and the latency associated with FLASH OS and/or FLASH file system required for managing the erase operation is eliminated. Another application for the IC's 1190 is as a replacement for conventional FLASH-based non-volatile memory in SSD's. Here, one or more of the IC's 1190 can be mounted to a PC board along with other circuitry and placed in an appropriate enclosure to implement a SSD that can be used to replace a HDD. As mentioned above, the IC's 1190 do not require the erase before write operation and it associated latency and overhead. For both RAID and SSD applications, the vertically stacked memory arrays allow for increases in storage density without increasing die size because the memory arrays are fabricated above their associated active circuitry so extra memory capacity can be achieved by adding additional layers of memory above the FEOL base layer die 754. The IC 1190 can be used in embedded memory applications in which data redundancy is desirable such as in portable PC's, cell phones, PDA's, image capture devices, and the like. Moreover, the data storage density can be increased by compressing the data as described herein and storing the compressed data in one or more planes of BEOL memory. In the above examples, the configurable memory interface as described herein can provide serial and/or parallel access to the memories in the above described circuits and systems (e.g., IC 1190). In some applications, the reduced interconnect/pin count associated with serial communication may make serial access more advantageous than parallel access and the memory interface can be configured for a serial access mode. In other applications, there may be an advantage to using parallel access (e.g., faster data transfer speeds) and the memory interface can be configured for a serial access mode. In yet other applications, it may be desirable to configure the memory interface for both serial and parallel access to provide both modes of accessing the memories.

In at least some examples, the structures and/or functions of any of the above-described features can be implemented in software, hardware, firmware, circuitry, or a combination thereof. Note that the structures and constituent elements above, as well as their functionality, may be aggregated with one or more other structures or elements. Alternatively, the elements and their functionality may be subdivided into constituent sub-elements, if any. As software, the above-described techniques may be implemented using various types of programming or formatting languages, frameworks, syntax, applications, protocols, objects, or techniques. As hardware and/or firmware, the above-described techniques may be implemented using various types of programming or integrated circuit design languages, including hardware description languages, such as any register transfer language (“RTL”) configured to design field-programmable gate arrays (“FPGAs”), application-specific integrated circuits (“ASICs”), or any other type of integrated circuit. These can be varied and are not limited to the examples or descriptions provided.

The description, for purposes of explanation, uses specific nomenclature to provide a thorough understanding of the invention. However, it will be apparent that specific details are not required in order to practice the invention. In fact, this description should not be read to limit any feature or aspect of to any embodiment; rather features and aspects of one example can readily be interchanged with other examples. Notably, not every benefit described herein need be realized by each example of the present invention; rather any specific example may provide one or more of the advantages discussed above. In the claims, elements and/or operations do not imply any particular order of operation, unless explicitly stated in the claims. It is intended that the following claims and their equivalents define the scope of the invention.

What is claimed is:

1. An interface comprising:
a substrate including active circuitry fabricated on the substrate; and
a plurality of non-volatile memory arrays fabricated directly above the substrate and in contact with the substrate, the plurality of non-volatile memory arrays are in electrical communication with the active circuitry, the active circuitry including
a mode module electrically coupled with a memory interface and a mode signal, the mode signal operative to indicate a serial mode or a radial mode, the memory interface operative to communicate signals including address, data, and control,
the mode module configured to select a serial connection from one of the plurality of non-volatile memory arrays to another one of the plurality of non-volatile memory arrays when the mode signal indicates the serial mode,
the mode module configured to select a parallel connection in association with the one of the plurality of non-volatile memory arrays and the another one of the plurality of non-volatile memory arrays when the mode signal indicates the radial mode,
the mode module including at least one serial module operative to provide the serial connection and configured to place another serial module associated with another one of the plurality of non-volatile memory arrays in the serial mode, and
a memory logic electrically coupled with the mode module, the memory interface, and the plurality of non-volatile memory arrays, the memory logic configured to electrically couple signals on the memory interface with the plurality of non-volatile memory arrays.

2. The interface of claim 1, wherein the active circuitry further comprises a controller configured to select the serial module independent of the parallel connection being selected, the controller electrically coupled with the mode module and the memory interface.

3. The interface of claim 1, wherein the serial module is configured to store an address operative to assign an identifier to the one of the plurality of non-volatile memory arrays.

4. The interface of claim 1, wherein the serial module is configured to compare a select value with an assigned value to determine a match, the assigned valued is stored in a non-volatile memory, and wherein the match causes the serial module to provide access to the one of the plurality of non-volatile memory arrays.

5. The interface of claim 1, wherein the serial module comprises a lock module configured to restrict a plurality of assignments to the one of the plurality of non-volatile memory arrays.

6. The interface of claim 5, wherein the lock module comprises a non-volatile memory that is positioned in at least one of the plurality of non-volatile memory arrays.

7. The interface of claim 1, wherein the plurality of non-volatile memory arrays are disposed among a plurality of memory planes that are vertically stacked upon one another and in contact with one another, the one of the plurality of non-volatile memory arrays is disposed in a first memory plane, and the another one of the plurality of non-volatile memory arrays is disposed in a second memory plane.

8. The interface of claim 1, wherein at least two of the plurality of non-volatile memory arrays are positioned on an identical memory plane.

9. The interface of claim 1, wherein at least a portion of one of the plurality of non-volatile memory arrays is configured as a register for storing non-volatile data.

10. The interface of claim 1, wherein at least one of the plurality of non-volatile memory arrays is a memory array that was last selected by the mode module prior to electrical power being removed, code is stored in at least a portion of the at least one of the plurality of non-volatile memory arrays, and the code can be immediately read over the memory interface without a selection sequence initiated by the mode module when electrical power is restored.

11. The interface of claim 10, wherein the code is read by a host system in signal communication with the memory interface and the at least a portion of the at least one of the plurality of non-volatile memory arrays is operative as boot memory for the host system.

12. A system, comprising:
a substrate including active circuitry fabricated on the substrate;
at least one layer of non-volatile memory fabricated directly above the substrate and in contact with the substrate, the at least one layer of non-volatile memory is in electrical communication with the active circuitry; and
a mode module configured to provide a serial connection from a memory array to another memory array in a serial mode and to provide a parallel connection from the memory array to the another memory array in a radial mode, the mode module is in electrical communication with a memory interface and a mode signal, the mode signal operative to indicate the serial mode or the radial mode, the memory interface operative to communicate signals including address, data, and control, the mode module configured to control access to the memory array and the another memory array in the serial mode or the radial mode, the mode module including a lock module and a selection module,
the lock module including
a first decoder configured to assign the memory array, and
a first memory configured to store data representing an indication that the memory array is assigned, and
the selection module including
a second decoder configured to detect a match between data representing an assigned value and a select value, and
a second memory configured to store data representing the assigned value;
wherein the active circuitry includes circuitry portions of the mode module, and wherein the at least one layer of non-volatile memory includes the memory array, the another memory array, the first memory, and the second memory.

13. The system of claim 12, wherein the assigned value is operative to configure the another memory array in the serial mode.

14. The system of claim 12, wherein the lock module is configured to restrict another command to assign the memory array.

15. The system of claim 12, wherein the lock module is configured to retain the assigned value in the absence of electrical power.

16. The system of claim 12, wherein the selection module is configured to restrict access to the memory array in absence of the match.

17. The system of claim 12, wherein the mode module is configured to access the another memory array using the assigned value from the memory array.

18. The system of claim 12, wherein the at least one layer of non-volatile memory comprises a plurality of memory planes that are in contact with one another and are vertically stacked upon one another with one of the plurality of memory planes in direct contact with the substrate.

19. The system of claim 18, wherein one of the plurality of memory planes includes the first memory and the second memory.

20. The system of claim 12, wherein the mode module is configured to provide access to the memory array from a separate layer of memory in the at least one layer of non-volatile memory.

21. The system of claim 12, wherein the mode module is configured to provide access to the memory array from a common layer of memory in the at least one layer of non-volatile memory.

22. The system of claim 12, wherein at least a portion of the at least one layer of non-volatile memory is configured as a register for storing non-volatile data.

23. The system of claim 12, wherein the at least one layer of non-volatile memory includes a non-volatile memory array that was last selected by the mode module prior to electrical power being removed, code is stored in at least a portion of the non-volatile memory array, and the code can be immediately read over the memory interface without a selection sequence initiated by the mode module when electrical power is restored.

24. The interface of claim 23, wherein the code is read by a host system in signal communication with the memory interface and the at least a portion of the non-volatile memory array is operative as boot memory for the host system.

25. A method, comprising:
establishing a serial connection to a back-end-of-the-line (BEOL) memory array;
receiving a select value via the serial connection;
retrieving an assigned value;
detecting a match between the select value and the assigned value; and
providing access to the BEOL memory array in serial mode.

26. The method of claim 25 and further comprising:
assigning the serial module with the assigned value; and
locking out subsequent assignment operations to assign the serial module with another assigned value.

27. The method of claim 25 and further comprising:
accessing a layer of multiple layers of the BEOL memory array to retrieve the assigned value;
performing the match in a front-end-of-the-line (FEOL) logic layer including active circuitry, the BEOL memory array is in contact with the FEOL logic layer, is fabricated directly above the FEOL logic layer, and is in electrical communication with the FEOL logic layer; and
providing access to the BEOL memory array at another layer of multiple layers of the BEOL memory array.

28. The method of claim 25 and further comprising: selecting the serial module to access the BEOL memory array until there is a mismatch between the select value and the assigned value.

29. The method of claim 25 and further comprising:
detecting a type of connection to the BEOL memory array is the serial connection;
providing a datapath to the BEOL memory array using the type of connection; and
coupling the serial module to another serial module to enable the another serial module to be assigned.

30. The method of claim 25, wherein the BEOL memory array retains data in the absence of electrical power.
